(19) United States
(12) Patent Application Publication
(10) Pub. No.: US 2026/0117458 A1
(43) Pub. Date: Apr. 30, 2026

(54) METHODS AND SYSTEMS FOR PLASMA COLOURATION AND PIGMENT FIXATION

(71) Applicant: XEFCO PTY LTD, Eveleigh, New South Wales (AU)

(72) Inventors: Thomas HUSSEY, Drummoyne, New South Wales (AU); Nathaniel ALKER, Seddon, Victoria (AU); Zhiqiang CHEN, Werribee, Victoria (AU); Robert VOLPE, Highton, Victoria (AU); Scott WHITBY, Kingsville, Victoria (AU); Marzieh PARHIZKAR, Waurn Ponds, Victoria (AU); Mingyu HAN, Point Cook, Victoria (AU); Amol PATIL, Charlemont, Victoria (AU); Alessandra SUTTI, Torquay, Victoria (AU); Surya SUBIANTO, Highton, Victoria (AU); Oliver LOTZ, Geelong West, Victoria (AU)

(21) Appl. No.: 19/118,658

(22) PCT Filed: Oct. 6, 2023
(86) PCT No.: PCT/AU2023/050974

§ 371 Date: Apr. 4, 2025

(30) Foreign Application Priority Data
Oct. 6, 2022 (AU) 2022902907

(51) Int. Cl. D06P 5/00; C23C 16/44; C23C 16/50; C23C 16/56; D06P 5/20

(52) U.S. Cl. CPC D06P 5/002; C23C 16/4408; C23C 16/50; C23C 16/56; D06P 5/2016

(57) ABSTRACT

A system for coating an article comprising a pigment applicator adapted to apply a pigment and a plasma module. The plasma module adapted to generate a plasma region. At least one of a chemistry and precursor can be supplied to the plasma generated in the plasma region such that the plasma region can at least in part polymerise the at least one of a chemistry and precursor to form a plasma polymerised coating. The pigment can be fixed to the article by the plasma polymerised coating.

### TECHNICAL FIELD

The present disclosure may be related to the application of colour to a substrate for the purposes of altering the visual appearance of the substrate. More particularly, the present disclosure may be directed towards the application of a dye or pigment fixed to a substrate with a plasma process.

### BACKGROUND

Conventional dyeing methods are well known within the art of textile manufacture. However, these conventional methods are generally wasteful and are unsustainable for the future of textile dyeing and dyeing or colouration of other objects.

Often these processes require large volumes of water, a large volume of chemistry and also a significant amount of energy and/or consume fossil fuels to achieve a finished product. Furthermore, the dyeing stage of textile preparation may be one of many steps which require the textile to be passed through a stenter or other system to dry the textile fabric. Further, based on the dyeing process, or colourant process for a textile, there is likely to required a specific process for natural or synthetic fibres or different textile compositions and thereby the complexity of these processes for different materials increases.

In view of the significant challenges faced by conventional dyeing systems and methods, there may be a need to replace existing methods and systems with more efficient and/or environmentally conscious alternatives to alleviate one or more issues.

Typically, textile materials may include materials such as fibres, yarns, fabrics, and textiles therefrom. Textile colourants in conventional processes may be provided as liquids generally solvents to dissolve dyes, or solutions or dispersions which contain pigments or powders.

Textile colourants are used to colour a textile and the colourant is generally the colour which is imparted to the textile, although the textile may augment or change this colour based on the opacity or other property of the dye or pigment. The bonding of the colourant with the textile is generally desired to be permanent, however the bonding strength is often less than desirable.

Some colourants may provide a chemical bond with the textile, while others may be a physical capture within the fibres of the textile, other may require an additional fixation chemical to bond the colourant with the textile. Dyes and pigments are commonly used for colouring textiles with dyes being generally provided in solutions and pigments generally being insoluble.

Dyes are generally used for penetration into fibres and provide a colour to the fibre from within. In contrast, pigments are generally not able to penetrate into a fibre and are deposited around the fibre and require a binder or other means of adhesion to retain the pigment in place. As these colouration mechanisms are substantially different, the methods to apply and colour a textile are also quite different.

A dye is typically soluble in water and may have an affinity for bonding with certain textiles. Textiles and dyes are generally attracted to each other due to chemical interactions between fibres of the textile and the dye chemistry. Some dyes may be reactive dyes and are attached to a colour molecule whereby a portion of the dye reacts with the fibre of the textile and the colour molecule remains with the desired colour attached to the fibre. These chemical reactions can form a number of different bonds of varying bond strength.

Pigments are generally not attracted to the fibres of a textile, and rely on a secondary component or binder to attach to said fibre. Pigments may be dissolved or suspended in solutions and based on the carrier medium.

In either case, for pigment or dye colourants to be applied there is required to be at least one wet process used to apply the colourant to the textile being treated. The wet process equipment, and the drying equipment are generally rather large and expensive items of equipment which also introduce a number of complications for the treatment of textiles. These complications relate to setting of fabric, shrinkage, stiffness, drapeability, and handfeel after treatment. These complications may require additional chemistry to be added to the wet processing steps to address these complications during drying, or even just due to the colouration process itself. Further, some of these additional chemistries can result in chalk marks or other defects being visually present which may require a further treatment process to resolve before being suitable for inclusion into a final product.

Conventional dyeing processes generally consume a substantial volume of water and often result in a large volume of waste chemistry, such as dyes, entering into the environment. Dyes significantly compromise the aesthetic quality of water bodies, increase biochemical and chemical oxygen demand (BOD and COD), impair photosynthesis, inhibit plant growth, enter the food chain, provide recalcitrance and bioaccumulation, and may promote toxicity, mutagenicity and carcinogenicity. Therefore reducing effluent may be advantageous.

In view of the disadvantages and restrictions of traditional dyeing methods, it may be preferrable to improve, alter or replace existing methods with more environmentally conscious methods and systems for carrying out said methods.

Any discussion of the prior art throughout the specification should in no way be considered as an admission that such prior art is widely known or forms part of common general knowledge in the field.

### SUMMARY

### Problems to Be Solved

It may be advantageous to provide for a system and/or method which can be used to dye natural and synthetic materials.

It may be advantageous to provide for a system which can dye or colour a substrate which reduces water consumption.

It may be advantageous to provide for a system which can reduce the carbon emissions relative to conventional dyeing and finishing processes.

It may be advantageous to provide for a system which can provide a dyeing process and a finishing process in a single roll-to-roll process.

It may be advantageous to provide for a dyeing method which can colour a single side of a substrate.

It may be advantageous to provide for a new dyeing method which requires fewer resources.

It may be advantageous to provide for a dyeing method which is a dry dyeing method.

It may be advantageous to provide for a fixation and/or binding process which can fix or capture particles, pigments and/or powders on the surface of an article.

It may be advantageous to provide for methods which can more efficiently dye a substrate.

It may be advantageous to provide for methods and processes which can bind particles to a surface of an article.

It is an object of the present invention to overcome or ameliorate at least one of the disadvantages of the prior art, or to provide a useful alternative.

### Means for Solving the Problem

In a first aspect there may be provided a system for coating an article. The system may comprise a pigment applicator which may be adapted to apply a pigment. A plasma module which may be adapted to generate a plasma region. At least one of a chemistry and precursor may be supplied to the plasma region generated such that the plasma region may at least in part polymerise the at least one of a chemistry and precursor, which may form a plasma polymerised coating; and wherein the pigment may be fixed to the article by the plasma polymerised coating.

Preferably, the system further comprises a post-plasma treatment module which may be adapted to treat the plasma polymerised coating. Preferably, the pigment applicator may be integral to the plasma module. Preferably, the plasma module may be contained within a chamber which may be locally purged to a purity of greater than 90% with a plasma gas. Preferably, the entry to the chamber may be fitted with a roller sealing the entry such that the plasma gas may be generally retained within the chamber and ingress of external fluids may be limited while optionally allowing the article to enter into the chamber. Preferably, the pigment applied to the article may be at least one of a; colourant, functional pigment, and a conductive pigment. Preferably, the plasma module may be adapted to supply the at least one of a chemistry and precursor to the plasma region such that the at least one of a chemistry and precursor which may form a plasma polymerised molecule before being applied to the article to form a plasma polymerised coating.

In a further aspect, there may be provided an article with a plasma coating. The article may comprise a surface on which pigment may be deposited. The pigment may be bonded to the article by a plasma polymerised coating, and wherein the plasma polymerised coating may be polymerised at a pressure of between 95 kPa to 105 kPa.

Preferably, a further deposition of pigment may be applied on the surface of the plasma polymerised coating. Preferably, the further deposition of pigment may be fixed to the plasma polymerised coating by a further plasma polymerised coating. Preferably, the pigment may be provided to the article during a plasma polymerisation step, such that the pigment may be bonded within the plasma polymerised coating at the time of application. Preferably, the pigment may be of a size which may be relatively larger than the thickness of the coating. Preferably, the pigment may be a colourant which may be a different colour than that of the article, such that the article may be imparted generally with a shade or similar colour as that of the pigment colourant. Preferably, the pigment may be a functional pigment adapted to released ions and/or diffuse ions while bonded within the plasma polymerised coating. Preferably, the plasma polymerised coating may be finished by a post-plasma treatment step to cure or otherwise treat an exposed surface of the plasma polymerised coating.

In the context of the present invention, the words “comprise”, “comprising” and the like are to be construed in their inclusive, as opposed to their exclusive, sense, that is in the sense of “including, but not limited to”.

The invention is to be interpreted with reference to the at least one of the technical problems described or affiliated with the background art. The present aims to solve or ameliorate at least one of the technical problems and this may result in one or more advantageous effects as defined by this specification and described in detail with reference to the preferred embodiments of the present invention.

### BRIEF DESCRIPTION OF THE FIGURES

FIG. 1 illustrates a schematic view of a system which comprises one or more treatment modules for treatment of an article;

FIG. 2A illustrates a side view of a system schematic which includes a plurality of chambers for treatment of an article;

FIG. 2B illustrates a side view of a further system for the application of a colourant to an article;

FIG. 3 illustrates a side view of another embodiment which can be used to apply a colourant to an article;

FIG. 4 illustrates a side view of an embodiment of a module and distribution system;

FIG. 5A illustrates a side view of an embodiment of a module for generating a plasma region; and

FIG. 5B illustrates another side view of FIG. 5A wherein a plurality of different plasma regions or fluid distributions are illustrated.

### DESCRIPTION OF THE INVENTION

Preferred embodiments of the invention will now be described with reference to the accompanying drawings and non-limiting examples.

### List of Features

1 Article
10 System
11 Terminal
12 Frame
15, (15A-15C) Chamber
18 Pigment applicator
20 Module
21 Post-treatment module
22 Housing
30 Power source
40 Fluid delivery system
45 Cooling system
50 Mixing chamber
55 Atomiser
60 Rollers
70 Recirculation System
80 Support
85 Pump system
90 Extraction system
95 Storage
100 Electrode
102 Core
104 Sheath
106 Channel
108 Fluid channel
110 Reaction gap
112 Plasma region
114 Gas tube
116 Aperture
118 Bias supply
120 Bias
130 Carrier fluid supply
140 Monomer supply
150 Pigment supply

There is described herein a system for treatment and processing of materials, which may include substrates, sheets of materials, 3D objects, and irregular objects collectively referred to as “articles” 1. While any desired article 1 may be treated with the system 10, several embodiments may reference substrates or other planar articles. As such, it is not a limitation of the system to only be used in the treatment of substrates 1.

The system 10 illustrated within different embodiments of the Figures comprise a number of plasma treatment modules 20 which are used to treat a substrate 1. They system is preferably adapted for plasma enhanced chemical vapour deposition (PECVD) processes whereby a plasma may be used to polymerise a chemistry, monomer or precursor to form a plasma polymerised coating or film. The treatment modules 20 may be shower head modules, spray modules, deposition modules, plasma modules, or any other treatment modules which can be used to activate a surface, or apply a coating to a surface which may apply a dry and/or wet coating to be cured. Is a dispersion is applied it may be desired that the dispersion fluid may be evaporated or otherwise removed before being exposed to a treatment module 20. Each module 20 may be removably mounted in the system 10 and be used to pre-treat, post-treat, treat, coat, cover, deposit, activate or perform any desired treatment process to an article 1. Preferably, the treatments imparted by a treatment module 20 comprise pigments and/or microparticles which are deposited after passing from the head through a plasma and onto an article 1, however a pigment applicator 18 may be a separate unit or module which can apply the pigment before being treated by the module 20.

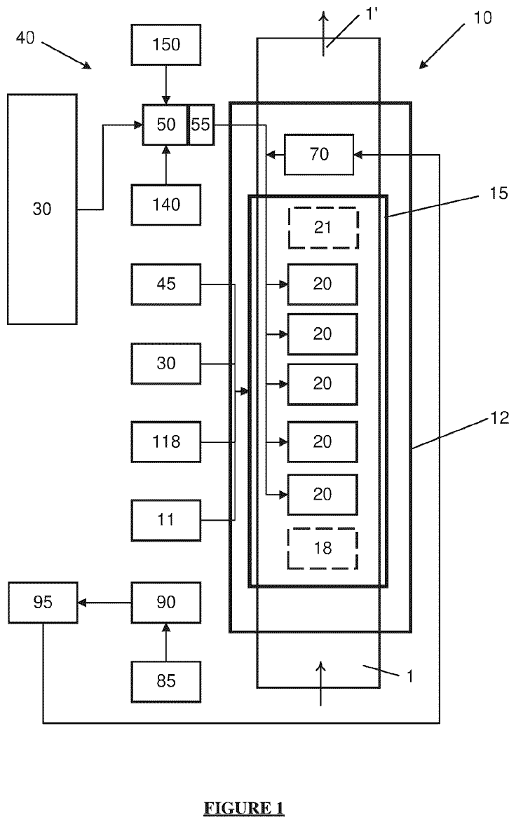

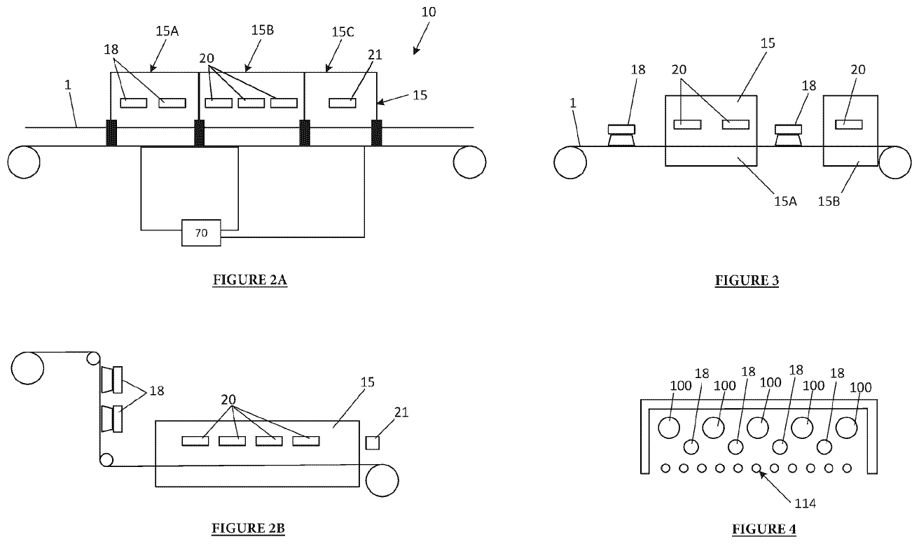

Articles 1 may be transported under a treatment head 20 by a transportation means. Any desired transportation means may be used, such as a conveyor, moving platform, rollers or any other predetermined means. Embodiments of a system 10 are illustrated in FIGS. 1 and 2 in which rollers are used to transport a substrate article 1 through the chamber 15.

In another embodiment, articles 1 can be placed directly below the treatment module 20 and the article 1 may be treated without being transported from a first location to a second treatment location. This can be of particular use if single articles 1 are to be coated or treated, rather than a series of articles on a manufacturing line. In this manner, the system 10 may function as a sterilisation device, surface activation device or a selective treatment system.

The treatment modules 20 may allow for at least one of; physical alterations, chemical alterations, coatings, application of films, surface activations, sterilisation, polymerisation or other desired treatment process. The system 10 may comprise any number of modules 20 to perform said treatments.

It will be appreciated that in some embodiments the chamber 15 may have a pressure above atmospheric pressure when using gas delivery tubes or pressurised plasma fluids. This pressure may be in the range of 10 pascals to 1 MPa. In some embodiments the pressure may be in the range of 95 kPa to 110 kPa, wherein ambient pressure is around 101 kPa. In other term, the pressure may be ±5 kPa relative to ambient pressure or 1 atmosphere. Unlike conventional systems, the pressure may be increased above atmospheric pressure, rather than decreasing in the direction of vacuum pressure. As such, the system 10 may be adapted to function at atmospheric pressure or above atmospheric pressure which is of particular advantage. Optionally, the pressure within the chamber 15 may have a negative pressure to assist with the extraction of gases and other fluids within the chamber 15. The negative pressure of the chamber 15 may be in the range of 90 kPa to 100 kPa, or a pressure ±10 kPa relative to atmospheric pressure, or in more specific embodiments a pressure ±1 kPa relative to atmospheric pressure.

Generally conventional plasma treatment apparatuses require a vacuum chamber or a low-pressure chamber in which articles are treated. Plasma is not commonly used outside of an enclosed depressurised chamber as there are a number of problems associated with the use of plasma in non-vacuum chambers. The generation of plasma may also be more easily generated and maintained in vacuum systems, however the present system 10 may have a generally pure chamber or controlled chamber of fluids which can address this issue while at around atmospheric pressure. While it may be relatively simple to provide gases to a chamber 15, it is relatively difficult to maintain the internal purity while also providing a chemistry for polymerisation, or allowing a polymerisation process to take place on a chemistry, monomer or precursor on an article. As such, the system 10 may be configured to have a series of interlocks or airlocks which allow for feeding of an article 1 while also reducing ingress or egress of fluids in and/or out of the chamber 15. Furthermore, one or more extraction locations and recycling systems 70 may be used to purify and refeed fluids back into the system 10.

Another problem with vacuum systems is even distribution or uniform distribution of carrier fluids and monomers contained therein. Another problem is the introduction of fluids into a plasma region or reaction gap which may cause polymerisation of dangerous/undesired molecules or ionisation of molecules which may damage a substrate 1 being processed or impact the quality of the treatment. As such, the system modules 20 described herein may be used to address these issues.

In addition to the above, another significant issue with existing systems is that they are required to operate at a level of vacuum. Not only does it take a significant period of time to achieve a vacuum, but injecting an aerosol will generally increase the overall pressure within the vacuum chamber, which can lead to non-function of the system. Aerosols injected into a vacuum will also disperse and therefore not be able to be used. As such, the system and method of the present disclosure will have significant advantages over the known prior art.

Another significant advantage of this system 10 is that the use of aerosols to deliver a monomer and/or pigment to a plasma region is possible for coating methods. Aerosols can be used to carry pigments, salts, organic particles or inorganic particles to a plasma region or to another desired location within the chamber 15. As suggested before, an atomiser can be used to convert at least one fluid to vapour or aerosol. The vapour may be considered to be a form of “mist”, which may include one or more species of monomer and/or one or more species of pigment. Optionally, pigments or other particles can be dispersed within the mist formed by an atomiser or vaporiser.

Aerosols may be supplied to the chamber 15 via the fluid outlets and subsequently introduced, either directly or by gravity, into the plasma region. The aerosols can be directed towards a plasma region with at least 50 % of the aerosol being passed through the plasma region and subsequently depositing onto a target area of the article 1. Using this method coatings of between 50 nm/min to 400 nm/min can be achieved. In some embodiments, a coating of between 100 nm to 300 nm can be achieved. In yet another embodiment, the deposition rate of a coating may be around 150 nm/min. The deposition of pigments may be independent of the coating thickness if applied separately, but may also have a deposition rate before a plasma polymerised coating is formed on said pigments. A loading rate of the pigment may be in the range of, 0.25 g/min per meter width to 360 g/min per meter width, but will depend on the pigment size being applied. Pigments delivered to the article 1 in some embodiments may be around 1.5 g/m²±0.5 g/m², or may generally be in the range of 0.5 g/m² to 5 g/m². The coating thickness may be the thickness of the plasma polymerised coating without pigments being present, or may be in addition to the previous deposition thickness of the pigment. For example, if a 400 nm thick pigment loading or layer is applied, and a 100nm plasma polymerised coating is applied, the total coating thickness may be in the range of 400 nm-500 nm thick, depending on the overall coverage of the pigment and the ability of the plasma polymerised coating to fill between pigments to form the final plasma polymerised coating with pigments embedded or fixed therein.

In contrast, systems which utilise vacuum pressures are not able to achieve a coating similar to this as introduction of aerosols into a vacuum or near vacuum will result in higher pressures, and will also result in immediate dispersion of the aerosols throughout the vacuum chamber rather than delivery to a target area or plasma region 112. Even if a plasma region 112 could be provided at the outlet for the aerosol, which would result in a number of plasma irregularities upon ejection of the aerosol, the particles will then disperse into the chamber and will not flow in a desired direction. Other disadvantages are also known with conventional systems which utilise vacuum pressures or lower pressures.

In yet another embodiment, the pigments may be entrained into an aerosol. In this way, powders or particulates of a desired size may be transported through the fluid system and to the plasma region 112.

In another embodiment, a separate stream of pigments or clusters may be provided, which mixes with the fluids exiting the outlets and directed toward the plasma region. Optionally, pigments may be sprayed, knife coated, wiped, or ejected onto the article 1.

Referring to FIG. 1, there is illustrated a system 10 which may be used to treat an article 1. The article 1 may be a substrate, which may be generally considered to be planar or 2D in nature, which can be treated via a roll-to-roll process. The article as illustrated may be a linear substrate, porous, non-porous, woven, non-woven, knitted or any other textile or film. Other embodiments of the system may allow for surface coating of 3D articles which may be passed through the system by conveyor, clamp, clasp, or any other holding mechanism. Alternatively, a 3D article may be treated in a fixed location, and treatment heads of the system may be moved to and from the article 1 to treat said article.

For example, a single chamber 15 may be provided which can firstly be used to distribute a pigment or particle coating to an article 1, and then the pigment applicator 18 may be moved or otherwise deactivated, and a plasma treatment device 20 may be moved into position and/or activated to provide a plasma coating and/or plasma treatment. Optionally, the same treatment module 20 may be configured to provide both a dye and/or pigment, which may be in a solution or carrier fluid, to an article 1 and also provide a plasma treatment and/or plasma coating to said article 1. The carrier fluid may be an aerosol, a vapour, liquid or gas, for example. More than one monomer supply may be present and selective introduction of fluids from within these supplies can be affected as desired.

In another embodiment, the system 10 may have a chamber 15 for a pigment applicator 18 which can apply a pigment to an article. One or more pigment applicators may be provided, which may be configured to provide the same pigments or a plurality of pigments, which may be unique pigments or colourants, per applicator 18. After application of a pigment to an article, the system 10 will transport the article 1 to a local region adjacent a plasma module 20, wherein the plasma module will provide to the article 1 a polymeric film or polymeric coating which has been formed by plasma. During the plasma polymerisation process, the article 1 may be adapted to be continually moving below the module 20 such that a continuous coating can be provided to the article 1. As the article 1 moves under the module 20 and receives a plasma coating, or has a coating polymerised on the article 1, the article 1 may enter into a treatment region for a post-treatment module. The post treatment module may be used to cure, finish, provide a lustre, provide a matt finish, or provide a texture to the plasma polymerised coating on the article.

It will be appreciated that in this embodiment the system 10 may be confirmed to provide a chemistry, monomer, or precursor to an article at the time of application of a pigment, and/or at the time of polymerisation. If both the pigment applicator 18 and the module 20 are adapted to provide a chemistry, monomer, or precursor they may be the same or different chemistry, monomer, or precursor. Further, regardless of the application device for the chemistry, monomer, or precursor, the plasma module 20 is preferably adapted to polymerise or substantially polymerise the chemistry, monomer, or precursor provided onto the article. The degree of polymerisation may also be dependent on the final use of the article, and the plasma module 20 may be adapted to only partially polymerise a chemistry, monomer, or precursor which forms the coating on the article 1. This may be of particular use for pigments which are to be releasably retained by the article, such as for medicament release. Other uses or applications may also benefit from a partially polymerised plasma polymerised coating.

A user terminal 11 may be provided in communication with the system 10 which can be used to input variables, select fluids, monitor the chamber(s), and start and stop a process. Any desired terminal interface may be used, and the terminal may control movement of one or more components of the system 10. Software may be executable and remotely updateable via the terminal. Preferably, a storage medium within the terminal 11 can be used to store data from processing and also store data in relation to errors or unauthorised use or access into the system.

Turning to FIG. 2A, the system 10 is illustrated with a first treatment chamber 15A, a second treatment chamber 15B and a third chamber 15C. It will be appreciated that all chambers 15 may be agglomerated into a single chamber 15, or two or more chambers may be used similar to as shown. The first chamber 15A may be a pigment application chamber 15A. Optionally, multiple pigment application chambers may be provided with a respective pigment applicator 18 which can be adapted to provide a predetermined pigment or colourant to an article 1. Having discrete pigment application chambers may reduce the potential for cross-contamination of pigments. If the pigment application chamber includes a spray applicator which may apply a dispersion or other liquid to the article 1, a further chamber (not pictured) may be included with the system which includes a drying segment. Alternatively, the drying segment may be within the spray applicator chamber 15A and may comprise at least one heater or device which may be used to remove liquids from the article before being exposed to the plasma region. The second chamber 15B may be a plasma treatment chamber 15B, and the third chamber may be a post-treatment chamber 15C with a post-treatment module 21. Post-treatment module 21 may comprise at least one of the following; a heating device, a cooling device, a further module 20, a plasma device, or a fixing or setting device which may be used to apply a further coating, finish a polymerisation process, alter the plasma coating applied by module 20. The chamber 15 is preferably sealable, and may form a fluid tight seal which can retain a desired local atmosphere. The chamber may optionally have an entry point and an exit point, such that planar articles 1 can be entered into the chamber 15 for treatment and taken out of the chamber after treatment. The entry point and an exit point preferably have a seal which prevents or substantially reduces the ingress of atmosphere outside of the chamber 15. Rollers 60 may be used to transport the article through the chamber 15.

Each chamber 15 may be adapted for a specific portion of the process, and each chamber 15 may have at least one of a discrete pressure, atmosphere, treatment module and length. The first chamber 15A may be used to apply a pigment to an article 1 via a pigment applicator 18. The pigment may be provided as a dry particulate, or may be provided carried or dissolved in a liquid. If the pigment is applied as a dry substance, the pigment may be ejected onto the article in such a way as to generally capture the pigment at the surface of the article, or provide a velocity to the pigment such that it may penetrate at least partially into the article 1. Penetration of a pigment may be of particular use when a textile is desired to be dyed or coloured with a colourant.

An interlock or airlock may be provided between the first chamber 15A and the second chamber 15B (similarly, the third chamber 15C may also have such an interlock or airlock) such that each respective chamber may be kept in a desired state and generally free of unmanageable volumes of contaminants. Each chamber used within the system may have airlocks, rollers, or fluid control devices at their respective entries and exits. Airlocks are preferably used to retain a desired atmosphere within the chambers and allow for a desired treatment to take place without unknown contaminants entering into the treatment process.

In yet a further embodiment, the system does not include an airlock between chambers. In this case chamber 15B may be adapted to have a relatively higher pressure than the other chambers such that the gases provided to chamber 15B will be urged towards the other chambers of the system.

In another embodiment, a high-pressure section may be provided between chambers which feeds the chambers with a plasma gas or other desired gas. This may urge fluids from the high-pressure section into the chambers immediately adjacent.

In yet another embodiment, the system 10 may be fitted with a pretreatment chamber which is before the pigment applicator chamber 15A which may be similar to that of the chamber 15C except that it functions as a pre-treatment chamber rather than a post-treatment chamber. The pretreatment chamber may be adapted to apply a primer to the article 1 to receive a pigment thereon. The pre-treatment chamber may alternatively be used to activate the surface or modify the surface of an article before a pigment is applied thereto. A primer may be a layer which is formed by HMDSO which has been at least partially polymerised, an argon plasma treatment, a nitrogen plasma treatment, or an oxygen plasma treatment. It will be appreciated that any of the reactive gases mentioned above may be mixed with argon or another inert gas in any desired ratio. Reactive species may be temporarily bonded with the surface of the article and may improve adhesion of pigment in the following application step. It may be advantageous to optionally allow for at least two reactive species of gases mixed rather than using inert gases such that the reactive species of gases can be used to augment or change the properties of a chemistry and/or the surface of an article.

The chamber 15 may be temperature controlled by gases injected therein, and the internal temperature of the chamber on average may be in the range of 15° C. to 35° C. In this range the article to be treated may have a superior deposition rate relative to temperatures outside of this range.

The temperature of the plasma fluid and/or the monomer may be in the range of 10° C. to 50° C. at the time of entering into the chamber. The excitation from the plasma region may increase the temperature of these fluids, thereby increasing the temperature of the chamber 15. Specific chemistries, monomers, and precursors may require a temperature which is up to around 250° C. for vaporisation or atomisation, and with these temperatures the temperature of the chamber may exceed the temperatures mentioned above, however this is also a possible desired embodiment of the system and the chamber may be adapted to allow for processing up to these temperature ranges. This is to say that the temperature of the vaporisation, evaporation, or atomisation fluids to be injected into the plasma region may be the temperature within the chamber if desired.

In another embodiment, at least one consumable of the system, such as; the carrier gas, monomer, plasma gas, pigments, or solution used with the system are temperature controlled individually. Each of these consumables can be temperature controlled to be within the range of −10° C. to +150° C. Other temperature ranges may also be applicable, provided that they are between the freezing temperature of a consumable, and the evaporation temperature of the consumable at the time of being either introduced to a fluid supply line or into the plasma region. It may be advantageous to increase the temperature of some consumables as this may increase the potential for fractionation when entering into a plasma region, and thereby creating a more durable coating or a coating with a desired property. In addition, a carried gas may be adapted to carry a greater volume of at least one of; the monomer or pigments by increasing the temperature of the respective monomer or pigments. Alternatively, the carrier gas temperature may also be increased to carry additional monomer and/or pigments.

Photoionization (PID) sensors, fluid flow sensors, temperature sensors or other fluid sensors may be used within the fluid delivery system 40 to monitor and control the distribution of fluids. The sensors may also be adapted to determine the concentrations and fluids extracted from the chamber for recycling in the recirculation system 70, which is discussed later. Based on the detected concentrations and compositions of the fluids extracted from the chamber 15 and injected into the recirculation system 70, the virgin fluid concentrations and volumes from the fluid supplies may be varied to create a more uniform mixture. It will be appreciated that the recirculated fluids and the virgin fluids may collectively create a desired concentration to be provided to the chamber 15. The desired concentrations to be provided into the chamber may be used to form a plasma region and/or a polymerised coating to be applied to the article 1.

In another embodiment, the recirculation system has a storage 95, which may be a tank or other receptacle. More than one storage 95 may be provided which may be used for storing separated fluids. For example, a first storage 95 may be used to store carrier fluids, and a second storage may be used to store monomer or partially polymerised monomer. The storage 95 can be used to temporarily store fluids which have been collected, and may be injected back into the recirculation system 70, or may be removed for further processing or purification.

An atomiser 55 may be used to atomise a monomer and pigment to be carried through the fluid delivery system to the reaction gap 110. The atomiser 50 may be found within the mixing chamber 50. In this embodiment, the module 20 with the reaction gap 110 may act as a pigment applicator in addition to a plasma polymerisation coating device.

A mixing chamber 50 may be used to mix the pigment and the monomer in predetermined volumes to allow for a desired ratio of monomer to pigment. A syringe or dosing means may be used to inject a predetermined volume of fluid of a monomer and/or a pigment fluid to be mixed within the mixing chamber 50, which can subsequently be atomised. The mixing chamber forming a part of the fluid delivery system 40.

The fluid delivery system 40 may also comprise a plurality gas tubes 114, or conduits, which are adapted to deliver a fluid into the chamber 15. The gas tubes 114 comprise a plurality of gas outlets 116 which allow for a pressurised gas to be distributed into the chamber 15. The gas outlets 116 may deliver a pure substance, such as a desired fluid, to the chamber 15. Desired fluids may include at least one of a monomer, a precursor, a chemistry, a plasma gas, a liquid, a reaction gas, a Penning ionisation gas, and a sacrificial gas. The gas outlets may also allow for at least one of a carrier fluid, monomer, monomer mixed with a pigment, pigment mixed with a monomer, to be delivered to the chamber 15. The monomer which can be polymerised, and pigments therein may be fixed within the coating, on the coating or under the coating formed on the article 1.

The gas outlets 116 may eject the fluids in such a manner that a stream is formed when the fluids pass into the plasma and towards the article 1. As such, a type of plasma stream may be formed which is unconventional as the plasma gas can be ejected into the chamber atmosphere before being excited to form a plasma at the electrodes 100. It will be appreciated that the above-mentioned plasma stream may be similar in appearance to a plasma torch well known in the art, however unlike a plasma torch the plasma stream is formed above an excitation area and forms a low temperature stream of plasma. This is advantageous as the stream can be formed by the pressure of the fluid delivery, and are adapted to move through a free area above the electrodes before entering into the plasma region 112. This provides the benefit of allowing carrier fluids to also enter into the region above the electrodes which can assist with smoothing the plasma generated between the electrodes 100, or creating a more uniform plasma which can extend across multiple sets of electrodes within the chamber 15.

A bias plate 120 may be used to attract ionised matter which can assist with increasing deposition rates or imparting a fluid movement to the ions. The bias plate is preferably disposed below the module 20, such that particles from the module 20 can be drawn down to the article 1. The bias plate 120 may be powered by a bias supply 118, or may be powered by the supply 30.

Preferably, the bias plate 120 is a DC bias plate which is negatively charged. Optionally, the DC bias may instead be an AC bias. It will be appreciated that the bias plate 120 may be positively charged if desired. Penning traps may be used above and/or below the plasma region, such that ionised matter in the plasma region can be repelled or attracted in specific directions. Preferably, if a Penning trap is used, the polarity of the Penning trap is opposite that of the bias plate if the bias plate is present. A magnetic field may also be used to induce movement of ions within a plasma region and can urge positive and/or negative ions in a desired vector or direction. In another embodiment, the bias plate 120 may be configured to be a DC bias plate or an AC bias plate which has a similar function to that of an electrode, such that the electrodes of a module may be of a uniform polarity and be the opposite to the polarity of the bias plate.

Referring to FIGS. 5A and 5B, there are illustrated embodiments of a treatment module 20. The module 20 comprises a housing 22 with a plurality of electrodes 100 mounted therein, and at least one gas outlet 116. The housing 22 being configured to support the electrodes 100 and the gas outlets 116 of the fluid delivery system 40.

The outlets 116 may be in disposed within a diffuser plate (not shown) which assists with distributing a carrier fluid and carried particles or fluids. In the embodiments shown in FIGS. 5A and 5B, gas tubes 114 are disposed with the gas outlets 116. The gas tubes are positioned relatively above the electrodes 100. In a preferred embodiment, the gas outlets 116 are positioned above a reaction gap 110 between the electrodes 100. In this way the gas outlets can focus gases towards the reaction gap 110. The number of gas outlets may be equal to or less than the number of reaction gaps 110, or may be up to 2 more than the number of reaction gaps. However, it will be appreciated that the number of gas tubes within a module may be any desired amount to allow for sufficient delivery of fluids to the electrodes 100 and/or into the chamber 15.

An article 1 is shown relatively below the module 20, and is configured to be passed under the module 20. Passing the article 1 under the module 20 allows for a coating or treatment to be made to the article 1. The first module 20 in the chamber may be optionally adapted to modify any remaining functional groups remaining on the surface of the article after pigment application. The functional groups may be modified by any desired plasma gas, and preferably is an inert gas. Modifying functional groups may be advantageous as some dispersants which could be used to apply pigments may be hydrophilic, and a desired coating may include a durable water repellent coating. Modification of residual functional groups may be desired to remove functional aspects such that a subsequent plasma coating may be more effectively applied to the article. Further, the modification may reduce the potential for the plasma coating's desired functionality to be weakened by an underlying residual functional group. For example, modification of a hydrophilic coating to a neutral or non-hydrophilic coating may improve the performance of a following hydrophobic coating.

Rollers 60 or a support 80 may be used to carry or transport the article from a first side to a second side of the module, wherein the article 1′ is a treated article. A plasma region 112 may extend across multiple electrodes 100 as is shown; if the electrodes are energised to maintain a plasma in the reaction gaps. It will be appreciated that the reaction gap is where the first instance of plasma may be formed, and the plasma region may ignite or otherwise excite atmosphere local the electrodes 100 causing a plasma glow. Preferably, the plasma glow is generally even and uniform between multiple sets of electrodes 100 and allows for a much larger area to be treated or coated at the same time that what could be possible with a plasma torch or plasma jet. Further, the plasma region formed by the electrodes is preferably above the article 1 to be coated, such that the plasma is not required to directly interact with the article 1, unless desired. Fluids, such as carrier fluids, atomised monomer, monomer vapour, monomer aerosols and/or pigments may enter into the chamber 15 from outlets 116. The fluids may disperse 124 outwards from the hole, or may be supplied with sufficient pressure to form a column 126 of fluid. The dispersed fluids 124 can be used to spread the fluids across the electrodes 100 and provide regions of varying fluid density. This may assist with the formation of a plasma region 112 which extends across multiple electrodes 100. Alternatively, the column of fluids may be ignited and form a plasma stream. This plasma stream may be used to form spot coatings or more focused coatings in some embodiments. Unlike conventional plasma jets, a plasma stream is a non-thermal plasma in which the plasma fluids may be ejected into the open chamber 15 before reaching the electrodes 100 to ignite or excite the plasma fluids. As such, the fluids injected into the chamber 15 can mix with local fluids within the chamber 15 before reaching the electrodes. This method of forming a plasma may also allow for other gases within the chamber 15 which are not ejected from outlet 114 to be entrained or collected to be carried to the reaction gap 110.

Optionally, the outlets 116 can be varied in size with the insertion of a nozzle or other flow direction or flow restriction device. The outlets 116 may be fitted with a thread or mounting means which can receive a nozzle to change the flow type or dispersion of a fluid entering into the chamber 15. Nozzles may also be used to direct the flow in a desired direction. Nozzles may also be fitted with a solenoid, iris or closure to seal the nozzle if desired. This may be of particular use when using multiple coatings or treatments in the chamber 15 as outlets can be selectively turned on or off.

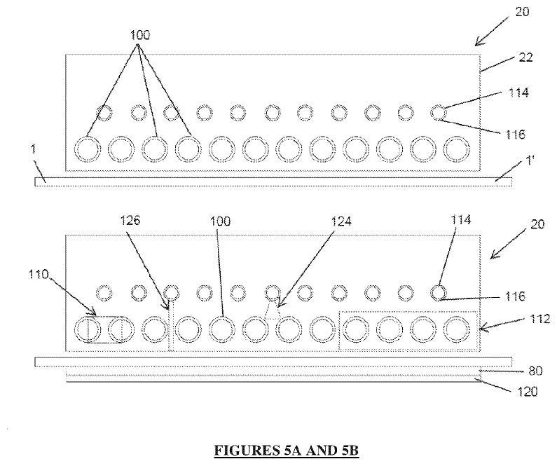

FIG. 4 illustrated shows a side view of an embodiment of a module 20, wherein the module includes a pigment applicator. The pigment applicator may be positioned relatively below a manifold which supplies at least one of a plasma fluid and a chemistry, monomer, and precursor to the article. In yet another embodiment, the pigment applicator 18 may be positioned relatively above the manifold of the module 20. The pigment applicator may be a plurality of tubular sections which can be used to deliver a liquid and/or pigment to the reaction gap 110 of the plasma region before application to the article. A fluid reservoir may be used to store fluids for the pigment applicator and the pigment applicator may have a predetermined dosing or control mechanism such that a desired volume of pigment is introduced into the plasma region.

Pigment applicators being part of the module 20 may have a number of advantages, notably a Penning ionisation effect may be possibly with the introduction of a pigment into the plasma region. Further, the pigment and/or carrier for the pigment may be used as a precursor which may be polymerised within the plasma. This may also be advantageous with respect to plasma polymerised dyes which may require one or two chemistries to be mixed and the subsequent plasma polymerisation may be used to impart the desired colourant and fixate the dye to an article.

In other embodiments, such as that shown in FIG. 2A, the pigment applicator may be separate from the plasma module and be adapted to apply a dispersion to the article 1. This may be beneficial as the dispersion liquids may be removed before the plasma region generated by a module 20.

The dispersion may be preferred to have a high concentration of pigment, wherein the pigment may be at least 30% by weight of the dispersion. More preferably, the pigment weight in the dispersion may be in the range of 60% to 90% of the dispersion. In another embodiment, the pigment may be applied without dispersant present and be applied “dry” on the fabric. The system may be adapted to dilute a higher concentration dispersion on demand. In this configuration a dose or known quantity of the dispersion may be mixed or otherwise combined with a fluid which may disperse the high concentration dispersion. This may be of particular benefit for articles 1 which may be different relative to other articles which may be treated within the system. For example, if the article 1 is a cotton substrate the dispersion may be diluted to a first dilution, and if the article 1 were a polyester substrate the dispersion may be diluted to a second dilution. Each dilution may be dependent on the composition of the article, particularly in the case of textiles and other substrates. While cotton and polyester are particularly named, each substrate type may have a unique dilution or may use similar or the same dilutions to apply a pigment to the substrate.

With respect to dispersions with a higher pigment concentration by weight, the dispersions may be more akin to a paste which may be diluted as required. Solvents or water may be used to dilute the paste in the system 10 before being provided to a spray system for applying the diluted paste to an article 1.

Dispersants may be used to dilute or provide a desired dispersability to a pigment dispersion. In at least one embodiment, the following dispersants may form part of a fluid with pigment to be delivered to an article 1; Tego Dispers 755 W with a 10-200% weight of pigment (wop), Surfadol XL167 Dispersant 10-50% wop, Disperbyk-199, dispersant, 20-150% wop, Tego Dispers 750 W, Lubrizol W150, Convey CT12, and Convey MT02. Other commonly used dispersants may be used with respect to this disclosure and the listed dispersants are not an exhaustive list. Optionally, a Hyperdispersant such as Lubrizol w100 may be use with a weight of pigment being in the range of 20-150%.

Wetting agents such as Surfadol TG may be used with the weight of pigment being in the range of 10-100%. Wetting agents may also be any other desired surfactants which may improve wetability. In addition, levelling agents such as polyox N12K (PEG 1,000,000) in the range of 0.01-0.1% weight by weight may also be used. Any desired combination of the above may be used within at least one embodiment of the present application.

The following are examples of pigment dispersions which may be used within the system Example 1, Irgazin Orange 2% weight/volume (w/v) with 15% weight of pigment (wop), TEGO Disperse 755 W, 0.05% w/v Polyox N12K. Example 2, Sicopal Yellow 2% w/v with 3% wop Lubrizol W100. Example 3, Navamin Carmine 2% w/v with 100% wop Surfadol TG, 30% wop Lubrizol W100, 0.1% w/v Polyox N12K. Example 4, Unifast Blue 2% w/v with 20% wop Surfadol TG, 20% wop Surfadol XL167, 0.05% w/v Polyox N12K. Example 5, Black Iron Oxide 1% w/v with 100% wop Lubrizol W100, 10% wop Surfadol XL167, 0.05% w/v Polyox 308. Example 6, Black Iron Oxide 1% w/v with 10% wop Surfadol TG, 30% wop Surfadol XL167, 0.05% w/v Polyox 308. Example 7, Roman Black 2% w/v with 50% wop Surfadol TG. Example 8, Vine black 2% w/v with 100% wop Tego dispers 755 W, 0.05% w/v polyox N12K. Example 9, Prussian Blue 2% w/v with 175% wop Tego Dispers 755 W, 0.05% w/v Polyox N12K. Example 10, Pre-reduced Indigo 60% (KraftKolor) with 55% wop Tego Dispers 755 W

The above examples are non-exhaustive and other pigments and dispersion additives may be used. It may also be preferred that additives are minimised as this may make any drying or heating processes more efficient and reduce the potential for reactive species to enter into the plasma regions generated by the modules.

In another embodiment, the pigment may be dissolved in a solvent and applied with the spray applicator to the article. The solvent may be evaporated by the heater segment and thereby precipitate out the pigment on the surface of the article.

FIGS. 5A and 5B comprises a number of circular electrodes, with the reaction gap 110 being the distance centre to centre of a circular electrode 100, as plasma can be formed between opposing polarity electrodes 100. Other electrode cross sections may be utilised depending on the desired plasma to be formed, a desired coating, or desired cooling for electrodes or plasma temperature. For example, square, rectangular, ovoid, or other regular shapes may be desired for electrodes. A cooling system 45 may be used with the electrodes 100 to cool the temperature of the sheath and/or the core to a desired temperature range. This may assist with reducing damage to articles 1 being treated. The cooling systems may be configured to be in communication with a fluid channel 108 of an electrode 100.

A bias 120 may be provided below the article 1, which can be used to attract the article and/or the fluids from the module 20 towards the article 1. Biases may also be used to impart a visual effect to the plasma region 112. For example, a bias may be used to create a more homogeneous plasma with a more even plasma which can promote a more desirable coating. The bias may be an electrical bias, such as a DC bias or an AC bias.

Methods for treating an article 1 may include providing a polymer to an article, having a generally sheet or planar form, in which the polymer has been formed by plasma polymerisation. The article 1 may have at least one fibre or yarn exposed at a surface which can be treated by the system 10. Polymers may be formed by plasma at atmospheric pressure wherein the energy of the plasma is sufficient to cause polymerisation of monomers and subsequent bonding of the polymer to an article 1. The thickness of the polymer coating applied to the article 1 may be dependent on the density of the plasma, the coating time, and the volume of monomer introduced into a plasma region.

In another embodiment, the carrier fluid and atomised matter can be delivered by delivery system 40 to the chamber and dispersed into the chamber through a diffuser plate (not shown). The diffuser plate may be disposed above the electrodes 100, such that the gases can be more evenly distributed to the electrodes 100 at a generally uniform velocity. This may reduce spot coating which can be achieved with the use of a pressurised gas from a gas outlet 116.

In yet another embodiment, the modules 20 may be fitted with a series of lasers, or other sensors, which can identify the location of an article relatively below said module 20. Once an article has been identified below the module 20, the electrodes which are directly above the article 1 can be selectively turned on to form a desired plasma. In this way the entire module 20 need not be activated or energised which can be of particular value as resources such as power, plasma gas, monomer, and pigments can be saved as they are not provided to the module 20 in regions which are not relatively above the article 1.

In yet a further embodiment, there is provided a method for depositing pigments on an article 1 comprising the following steps atomising a colloidal solution (or suspension) including pigments and introducing the solution into a plasma region and depositing the pigments and on a surface of said article 1 in an atmospheric plasma.

A pigment may be an aggregate of small molecules, or an assembly of a few hundred to a few thousand atoms, forming a particle, for which the dimensions are in the range of 1 nm to 1000 nm, or more preferably in the range of around 200 nm to 1000 nm. Larger particles may also be carried by the carrier fluid, bonded with the monomer, or otherwise transported with aerosolization, vaporisation or evaporation of the monomer.

A power source 30 may be a generator or other mains powered device which can supply power to the system and components thereof. For example, the power supply can be connected to a treatment module within the chamber 15. A cooling system 75 may also be used to cool the system during use, and in particular may be used to cool at least one of the treatment modules 20, electrodes 100 and a bias plate 120. The article may be supported on a support 80, below which the bias 120 can be disposed. The bias may be a DC bias (or AC bias) or other electrical bias which can assist with controlling plasma and/or directing flow of particles from a plasma region 112. This may further encourage polymerised monomer and/or pigments therein to flow towards and deposit onto the article 1.

The system 10 comprises at least one pair of electrodes 100 which can be used to ignite or strike a plasma gas to form a plasma, which may be a dielectric barrier discharge. The space between the electrodes 100 may be referred to as a reaction gap, wherein a reaction between a voltage and a plasma fluid may be observed, or where polymerisation or fractionation of a monomer or polymer occurs. Fractionation of a monomer may be within a plasma region 112, which may be above, below or between electrodes, as is exemplified within FIG. 5B. After fractionation the molecules formed from the monomer flow in the direction of the ejection, or a localised electric or magnetic field, and preferably towards the article whereby the fractionated molecules recombine to form a polymer which is preferably crosslinked, or highly crosslinked, which may then form a chemical bond or physical bond with the article 1. A plasma region 112 is formed within a reaction gap 110 and may fill the entire reaction gap 110, or a portion thereof. The space between electrodes 100 may be in the range of 1 mm to 12 mm depending on a desired plasma density, and said space may be the reaction gap 110. The space between electrodes 100 may be from sheath to sheath of adjacent electrodes 100, or centre to centre spacing of adjacent electrodes 100. It will be appreciated if the spacing is sheath to sheath, the distance between core to core will be greater.

Dielectric barrier discharges are typically characterised by the presence of at least one dielectric barrier, such sheath 104 and a reaction gap 110 located between a respective pair of electrodes 100. Dielectric barrier discharges may have the ability of breaking chemical bonds, exciting atomic and molecular particles, and generating active particles such as free radicals. Dielectric barrier discharge systems may be referred to as; “non-thermal systems”, or “nonequilibrium systems”, or “cold plasma systems”.

In contrast to non-thermal systems, thermal plasmas have electrons and heavy particles at the same temperature, and are therefore in thermal equilibrium with each other. However, non-thermal plasmas are usually characterised as containing ions and uncharged particles (heavy particles) at lower temperatures than electrons. Since the temperatures of the heavy particles in the plasma remain relatively low, excluding any undesired polymer degradation, dielectric barrier discharge burners have been described as suitable for polymerization and deposition processes. The inherent advantage of dielectric barrier discharge systems over other conventional thermal plasma systems is that non-thermal plasma conditions can be easily set at or near atmospheric pressures, and may also be used to treat or polymerise monomers and/or polymers.

The plasma may be generated by a discharge between electrodes 100 in which a plasma gas can be excited or ionised to form said plasma. Any predetermined method may be used to generate a plasma including; alternating current (AC) excitation, the direct current (DC) excitation, low-frequency excitation, RF excitation and microwave excitation methods. Each of the aforementioned methods may be used to generate an atmospheric pressure plasma. “Atmospheric pressure plasma”, also referred to as normal pressure plasma, may be a plasma in which the pressure is approximately equal to the atmospheric pressure. It will be appreciated that the pressure within the chamber 15, even when filled with a desired local atmosphere, will have a pressure similar to the pressure outside the chamber 15. In at least one embodiment, the pressure internal the chamber is around 1 bar to 5 bar, however other pressures greater than 1 bar may be used.

As the plasma module 20 can be used in ambient atmosphere, a carrier fluid for generating a plasma in the reaction gap 110 may be pumped into the region between the article 1 and the module 20 for a predetermined amount of time such that ambient atmosphere is evacuated from the region before igniting the carrier fluid such that ambient atmosphere molecules are not ionised or activated. The region between the article 1 and the module 20 may be referred to as a “local region”. Purging ambient atmosphere may also be desirable if the system 10 is used within an enclosed chamber such that functional treatment properties can be controlled. For example, purging the chamber 15 may be advantageous as this may allow for the removal of oxygen within the chamber 15 which can react with monomer species or polymerising species.

At least one further fluid may be provided to the plasma region 112 which is carried by the carrier fluid, or injected directly into the plasma region 112. The further fluid will typically be used to treat a substrate 1 or apply a coating. In one embodiment, the further fluid may be a monomer which can be polymerised by the plasma region, and may be used for a plasma enhanced chemical vapour deposition (PECVD). Optionally, the further fluid is provided to the plasma module 20 by at least one further inlet. If a carrier fluid and at least one further fluid are provided to the module 20 the fluids are preferably mixed together in a desired ratio such that a known amount of further fluids can be delivered to a substrate 1 via an outlet.

The monomers may be injected into a plasma chamber 15 as a liquid spray, a vapor or atomised particles and may assist with forming desirable plasma conditions as monomers the monomers may be adapted to stabilise a plasma streamer or plasma corona condition which is formed in the reaction gap 110. Stabilising a plasma condition may mean forming a plasma glow or a stable plasma within the reaction gap 110. It will be appreciated that the voltage and the frequency supplied to the electrodes 100 will also assist with maintaining and/or forming a stable plasma.

In yet a further embodiment, if the article 1 is a substrate, the plasma may be used to treat only a first side of a substrate, while the second side of the substrate may be protected from treatments, or may be separately treated by a different coating or treatment process. This may allow for selective modification of one side of a substrate. Protection of one side of the substrate may be achieved by application of a film or protective layer on the second side of the substrate, or by pressing the second side of the substrate against a surface which will not allow coatings or treatments to be applied to said second side of the substrate.

The power source 30 may comprise more than one power supply unit. A power source 30 can be coupled with a respective module 20, such that the module 20 can be activated, deactivated, altered or otherwise manipulated by a user of the system for a desired treatment process. Each module within the system may have a unique or discrete power source 30 which can be activated as desired. Alternatively, power source 30 may be used to power one or more modules and/or components of the system 10. The power source 30 may also be an RF source to charge RF electrodes, or may be an AC (alternating current) or DC (direct current) power source 30. Electrodes 100 may be formed from with a core with a sheath 104 covering the core 102. The core 102 is formed from a conductive material, such as copper, gold, or stainless steel for example, and the sheath 104 is preferably a dielectric material, such as glass or alumina. The core 102 is preferably a conductive material which can withstand heating to temperatures which are equal to or less than that of the plasma formed in the plasma region. The sheath 104 selected is to be formed from a dielectric material which can encompass or encapsulate the core 102 to reduce arcing and assist with stabilisation of plasma formed in the reaction gap 110. Optionally, a fluid channel 108, such as an air gap or liquid gap, may be provided around the core 102 which can assist with cooling and dielectric properties of the electrode 100. For example, air or inert gas may be used as a cooling fluid which may be passed between the electrode core 102 and the sheath 104. In another embodiment, the electrode 100 is provided with one or more fluid cooling channels or a cooling channel which is used to cool the electrode 100. Optionally, the core 102 may be provided with a fluid channel through which fluids can be passed to cool the electrode 100.

While electrode sheaths 104 may be a rectangular shape or circular shape, the core 102 may be any predetermined shape which may or may not correspond with the shape of the electrode sheath. For example, an electrode 100 may be a blade type electrode 100 which has a rectangular sheath cross section, however the core may be circular or any other predetermined shape. Fluid conduits may have any predetermined cross section, this may include a regular shape, a sinusoidal shape or a waveform shape cross section. The general shape of the sheath 104 may define the type of electrode 100 regardless of the cross section of the core 102, however there may be advantages in relation to conforming the shape of a core 102 with the shape of the sheath 104.

As the system is functional as an atmospheric pressure plasma system, the chamber 15 does not require a vacuum pressure to operate. Cleaning, functionalisation, and activation of an article 1 can be achieved via different plasma treatment methods and exposure to plasma. In ambient atmosphere, the functionalisation may impart groups comprising at least one of; oxygen, nitrogen, and hydrogen groups. In another embodiment, the plasma may be used to etch a surface or otherwise modify the surface by removing matter from said surface.

If a surface is activated, reactive groups may be present at the surface which can form superior bonds with particles that interact with the surface. In another embodiment, the pigments may be activated by the plasma, either directly by forming physical bonds, or by reactions at the surface of the pigment.

Any contaminants that pass between chambers may be urged towards an extraction location, in which each chamber 15A-15C may be fitted with one or more such extractions.

The extraction location may lead to a venting system or a recirculation system 70. If the contaminants are directed towards a recirculation system 70, the contaminants may undergo purification processing. Purification may involve at least one of the following stages; a combustion stage, a cooling stage, a heating stage, a capture stage, and a venting stage. Each stage may be used in combination with another stage, or be implemented in any desired manner, and multiple of the same stages may also be used with the recirculation stage.

Collection and recycling within the chamber 15 may be achieved with the used of an extraction location. Multiple extraction locations may be positioned around the system which can be used to draw in fluids and by-products which are desired to be removed from the system chamber 15. Filtration may be required to separate larger particles from the collected by-products and gases and smaller particles may be transported further downstream for collection, purification, and/or removal. A filtration stage may be the first separation process for the recirculation system 70 which received products, such as fluids and particles, from one or more extraction locations.

Preferably, a cryogenic cooling stage is used to freeze out some contaminants and allow for plasma fluids to be reused within the process. The cryogenic cooling stage may be a cyro-separation process, whereby heat exchangers and separation columns can be used to separate out argon from other gases and particulate contaminants. Compression of gases may take place at the inlet of the recirculation system. The gas inlet stream to be recycled can be cooled and preferably partially liquified. Separation of nitrogen, oxygen and argon may be achieved through the cryo-separation process. In some embodiments, gaseous nitrogen and oxygen may be separated from liquid argon and may then be reinjected into the system, stored, or released.

In another embodiment, the recycled gases may have further contaminants added which can be reliably combusted or reacted with other impurities within the recycling system. These materials may include oxygen, nitrogen and/or hydrogen. Preferably, contaminants removed from the recycled gas stream are water and CO₂, however siloxanes, pigments, solvents, solutions, alcohols and other contaminants may also be captured and disposed of in a desired manner. It will be appreciated that the chemistry to be polymerised will may be a primary source of contamination, with pigments and solvents/solution from the application of pigments also contributing to the contaminants. As such, the by-products of the system may be known only when specific colourants are selected, and the recycling process may be adapted to suit specific recycling needs. However, it is preferred that at least a purified plasma gas is returned for use in the system for additional treatment. A top-up or makeup plasma fluid may also be included with the recovered plasma gas as the recovery rate will be less than perfect.

Further, it may be preferred that the purified gas may be returned to the system for further article processing at a desired temperature. The temperature of the plasma gas, for example argon gas, may be in the range of around −30° C. to 40° C.

More than one extraction location may be provided within the chamber(s) 15 with each extraction chamber adapted to filter at least one of gases and particulates which enter. Gases, particles and other fluids which enter into the extraction location can be provided to the recirculation system 70.

The pigment applicator in the first chamber 15A is preferably any device which can be used to supply or impart a pigment to an article. The pigment may be dry at the time of application, contained in a binder, dispersed in a dispersion, in a solution, or dissolved in a solvent. More than one pigment and state of pigment may be applied to an article within the first chamber 15A. Pigment applicators may be positioned relatively above an article as shown in FIG. 1, or may be disposed relatively parallel to the direction of movement of the article 1 similar to that as shown in FIG. 2.

A pigment applicator disposed in a vertical orientation may allow for a trough or extraction location to be disposed below the pigment applicator and allow for the vertical ejection of the fluids from the applicator to the article 1. Excess fluids and/or pigments from the applicator that did not adhere to the article can then be gravity assisted to the extraction location. Pigment applicators can eject fluids in any desired manner and may eject fluids in a relatively straight line, or eject fluids in an arc or fan towards the article. Pigment applicators may be disposed in any desired orientation as desired, and may be positioned 1 mm to 500 mm from the surface of the article 1.

More than one applicator may be disposed within the chamber 15, 15A. A pigment applicator may also be disposed on either side of an article, such as a substrate and may allow for the coating of an article in two directions. Furthermore, having more than one pigment applicator may allow for more than one type of pigment to be applied simultaneously on one or more surfaces of the article 1, or the same pigments can be applied to both sides of the article to allow for a multiple side application of pigment.

Pigments may be colourants and/or functional pigments which are applied to the article 1. Dye pigments may also inherently include some functionality if desired. For example, colourants formed from metal oxides may also have functionality which could be applicable for antiviral or antibacterial treatments, which may be the case for copper oxides.

Some pigments may be selected for corrosion resistance, which may be corrosion inhibitive pigments (CIP), which may allow for diffusion of a fluid, such as water or air, such that the pigment may be dissolved, or partially dissolved. Some pigments may have a higher or a low pH which may be beneficial for different environments and respective corrosion resistance. It may be preferred that CIPs are formed with metal ions which may be derived from metal cations such as zinc, copper, titanium, brass, strontium, chromium, lead, molybdenum, aluminium, calcium, and barium. Alternatively, the pigments may be anions, such as those derived from phosphorous (orthophosphoric and polyphosphoric acids), chromic acid and boric acid.

Another pigment which may be elected is a conductive pigment. These pigments may be formed at least in part from materials selected from the group of; copper, iron, silver, nickel, silver-coated nickel, carbon black, multi-walled and single-walled carbon nanotubes, as well as other material.

Thermally conductive pigments may allow for electrical conductivity, and may also allow for improved heat transfer, which may be advantageous for flexible products and products where heat is desired to be transferred from the contact face.

Optionally, the plasma coating that is formed to fix the pigments with the article 1 may also have a conductive capacity, such that the pigments may be guaranteed to have a path for conduction, or may assist with thermal transfer. Conductive pigments may generally be applied in one or more layers, which may be similar to laminations. Each layer of the pigments may have a unique pigment, filler, binder, and/or particle size. The differences between the laminations may also allow for a desired functional property to be imparted to the laminations which may be useful for battery applications.

Each of the laminations may undergo a plasma treatment, or have a plasma coating imparted to the pigments to build the laminations. The overall structure regardless of the number of laminations may be referred to as a coating, and is preferred to be a plasma coating as the layers or laminations will have undergone a plasma treatment.

Conductive pigments may also have utility for electromagnetic shielding and may be disposed in any predetermined pattern or array on an article which may allow for selective conductive or EM blocking or shielding.

In another embodiment, electrically conductive coatings may be formed from electrically conductive pigment with a non-conductive resin binder. The binder holds the pigment together and a conductive filler provides an electrical pathway. Electrical charges travel through the conductive fillers, making short jumps through the matrix between particles when necessary.

Pigments in these coatings may be preferred to be in the form of flakes, plates, tubes, or elongate elements, although any pigment geometry may be used if desired. Carbon powder, nickel flake, silver-coated-copper flake, and silver flake may be used as a pigment in these applications. Fillers for these coatings may be preferred to be carbon based as these are generally cost-effective fillers and allow for conductive applications, grounding applications and EM shielding applications. Silver pigments may be preferred when requiring a high conductivity and/or a high frequency EM shielding.

In another embodiment, the pigment applied to the article 1 may comprise ferromagnetic powders, such as Fe—Co, Fe—Co—Ni, Fe—Co—Co—Ni, Fe—Co—B, Fe—Co—Cr—B, Mn—Bi, Mn—Al, Fe—Co—V alloys, bronze powder, and other alloys of transition metals.

The binding for the pigments is preferably the plasma polymerised coating which is formed by the module 20. The plasma polymerised coating may determine the adhesion, durability, chemical resistance and handfeel of the coating. It is preferred that the polymerised coating is applied such that pigments applied by the pigment applicator can be fixed to the article. It may also be preferred that coatings applied have one or more functional properties which may be commonly desirable within the electronics, energy storage, and/or clothing industries.

After application of the pigments to the article 1, said article 1 is then subsequently subjected to a plasma treatment module 20. The plasma treatment module 20 may be adapted to polymerise a monomer or precursor which acts as the solution or solvent for the pigment. Alternatively, the plasma modules 20 may be adapted to supply a monomer and/or precursor to the plasma region to be polymerised and form a film or coating over the pigments provided by the pigment applicators.

The plasma formed by the plasma module 20 may be a glow plasma which can be formed in atmospheric conditions or near to atmospheric conditions. Conventional plasma systems generally require that a vacuum pressure chamber be used to generate a glow plasma, however the present system is adapted to generate a glow plasma within the range of 95 kPa to 110 kPa. It may be preferred that the pressure within the chamber 15 is in the range of 99 kPa to 102 kPa such that the internal pressures of the chamber are not substantially dissimilar to external atmospheric pressures and thereby reduce the ingress and/or egress of fluids to and from the system respectively.

Glow plasma intensity may be controlled by the flow rate of the plasma gas, a Penning ionisation gas, a Penning ionisation chemistry, or the voltage applied to the electrodes of the module 20. The electrodes 20 may be ordered in an array which can form a plane or axis of plasma, which may define a plasma region of the module. A plurality of positive and ground electrodes may be used within a single module 20 with the electrodes for generating a plasma therebetween being spaced between 1 mm to 12 mm surface to surface. A dielectric barrier discharge (DBD) may be the electrical discharge between two electrodes separated by an insulating dielectric barrier.

Preferably, the electrodes are formed with a conductive core and a dielectric barrier sheath or covering the conductive core. The thickness of the dielectric may be in the range of 0.1 mm to 6 mm, and the core of the electrode having a thickness of 0.1 mm to 6 mm. The conductive core may be circular, wherein the diameter of the core is in the range of 0.1 to 6 mm. Optionally, the core may be formed with a channel therein for a coolant to pass therethrough, and cool the core and sheath forming the electrode.

Treatment of articles such as textiles are generally limited in their ability to withstand thermal temperatures, as such the temperature of the plasma is preferred to be a cold plasma, or a plasma has a temperature less than around 200° C. at any location of the plasma region which is likely to interact with the article. The parameters which may be controlled by the system include plasma gas, residence time of plasma gases and reactive species, plasma gas and reactive species flow rates, frequency, power, pressure, ambient temperature, aerosols, vapours, electrode spacing, bias plates, and temperature of the gases, monomers and electrodes.

The modules 20 may be powered by an AC RF power supply, or a DC power supply. Different power supplies may have different impacts on the formation of plasma, pulsing of plasma, and the overall energy required to strike and maintain a plasma. Modules 20 may be fitted with a striking device which allows for a high energy input which can cause an excitation of plasma gases to form the plasma, with a lower energy input required to maintain a stable or desirable plasma thereafter. Striking devices may be integral to the power supply, or may be fitted to the supply. Plasma striking may require 1.5 to 10 times the voltage required to ignite a plasma, compared to maintaining the plasma.

The voltages required by the electrodes may be in the range of 20 V to 80 V primary voltage, and 1.5 kV to 6 kV secondary voltage. The power required per unit area for the plasma being in the range of 0.1 W/cm² to 2 W/cm², however it will be appreciated that the overall geometry of the module 20 and the electrodes may have an influence on the plasma region and the resulting plasma density. The power output may be in the range of 500 W to 4500 W per module. It will be appreciated that the power and the voltage required may change based on the plasma gas and the monomer or precursor to be polymerised.

A pulsed or duty-cycled power supply may be desired such that the formation of plasma or intensity of plasma can be varied as desired. It may be advantageous to have a duty cycle in the range of 5% to 60% such that active species can be formed within the plasma and be imparted to the article, or an existing coating or pigment thereon, without forming undesired species during the polymerisation step. The plasma modules 20 may have a pulse applied to the plasma intensity which can also allow for control over the deposition rate and deposition species formed within the plasma region before the species are deposited onto the article 1.

An article passing under a first module 20 may receive a coating or lamination. Subsequent modules 20 may be used to apply a further coating, a further lamination, and/or a continuation of the coating applied by the first module 20. Any number of coatings may be applied to an article, and spacing between modules and/or electrodes of modules may allow for distinct layers of a coating to be applied which may be desirable for durability of the final overall coating applied to an article, and may further assist with fixation of a pigment to the article 1.

Optionally, laminations can be provided whereby application of pigment may be after the application of a plasma coating, and a further plasma coating can then be provided over the pigments such that the pigments are disposed between the plasma coatings/films. In this way the pigments may be encapsulated, or relatively more embedded within the plasma coatings which may secure the pigments in a more desired location. Any number of laminations can be provided by the system.

A post-treatment module may be provided in the third chamber 15° C., or chamber 15. The post-treatment module may be selected from the following group; a heating element, an abrasion element, an abrasion roller, a compression roller, a laser, a sintering device, a radiation lamp, an electromagnetic radiation means, and a light exposure device. The aforementioned post-treatment devices may be utilised to augment or finish a coating applied during the first chamber and/or second chamber.

More than one post treatment module may be within the chamber 15, 15C, or may be external the chamber in open air, such that an inspection can also be carried out during the final post-treatment step.

While a post-treatment step may be imparted to the article to finish or augment the coating, the system 10 may be adapted to allow for a coating to be provided to an article 1 such that the module 20 provides a fully, or near fully plasma polymerised coating which offers the desired properties, which may fixate a pigment therein, without the requirement for a post-treatment process.

plasma coating will be any coating which is formed by plasma, whereas a plasma treatment may be the use of plasma to alter or augment the surface of an article or react chemistry applied to an article. It will be appreciated that a plasma treatment may form a plasma coating by polymerising a monomer or precursor which is already on an article, or may be passed from the outlets of the manifold through the plasma before being deposited onto the article 1.

Plasma modules 20 may be formed with a housing channel in which a supply manifold is positioned, and at least one electrode pair. The housing channel defining an open plane through which plasma gases and/or chemistry may be supplied to an article. Electrode pairs are preferred to be positioned near to the top of the channel and the manifold positioned relatively below the electrodes.

FIG. 2B illustrates a further embodiment of a system which is adapted to provide a pigment to an article. The pigment applicator as shown is configured to eject or spray pigment in a generally horizontal direction such that the article can be passed in a vertical direction. Shown is a planar article 1 which may be a textile substrate. The spray from the pigment applicator in this configuration may be more concentrated to a smaller region which can limit excess pigments from being distributed in a larger area. Further, a first pigment applicator may be provided on a first side of the substrate article and a second side of the substrate article 1. Optionally, a collection tray or similar collection device may be positioned below the applicator 18, such that excess pigment is collected and is not falling onto the article moving below where pigment would fall under gravity. The collection tray may be connected to one or more extraction locations for removing the pigment and any fluids associated with its application or carrying. In another embodiment, the article does not move under any pigment drip or gravity falling location such that the article may not be inadvertently treated with excess fluids or pigment.

The plasma modules 20 may be housed within a chamber 15, or may be exposed to atmosphere where a localised purge is conducted prior to striking plasma to ensure a high purity of plasma gases are excited. The plasma modules are preferably adapted to supply the chemistry to the article 1 which is polymerised, whereby the pigment applied by the pigment applicator can be fixed by the plasma coating supplied from the plasma module. This method of application of a coating is unique and provides a smaller particle for polymerisation relative to conventional methods where a coating to be polymerised is applied before being passed to a plasma treatment area.

The methods used by the system to apply a polymeric coating to the article are preferably PECVD methods. PECVD methods allow for fractionation before application of a recombined plasma polymer is formed on an article 1 target surface. PECVD may allow for a larger range of chemistries and precursors to be used as fractionation can allow for breaking of bonds more effectively compared to attempting a polymerisation of an insitu coating introduced into a plasma for polymerisation. Furthermore, enhanced or improved bonding may be formed between the article 1 and the film or coating formed by a PECVD process. In addition, due to the inherent limitations of thicknesses of coatings applied for a post-polymerisation process, the thickness of coatings applied in non-PEVCD processes are likely to be substantially thicker as a minimum thickness and may have difficulties forming a fully polymerised coating or an evenly polymerised coating, while also having a generally weaker bond being formed with the article after polymerisation. As such, PECVD methods may have inherent advantages over traditional coating methods, or post-plasma polymerisation methods.

Having a pre-applied coating which is to be polymerised may require a higher power transfer to effectively polymerise the coating applied. Further, the thickness of the coating applied in pre-application methods will generally be relatively thick compared to coatings which are formed by plasma polymerising techniques whereby a chemistry is passed through a plasma region before being applied to an article. As such, a more complete polymerisation with reduced energy consumption may be achieved with a plasma coating module relative to a plasma treatment module whereby an existing chemistry on an article is polymerised.

FIG. 3 illustrates another embodiment which illustrates a plurality of pigment applicators and a plurality of plasma treatment modules. In this configuration a first pigment applicator can apply a first pigment to an article. The article 1 is then processed into a chamber 15 which comprises a plasma treatment module 20. Plasma treatment module 20 is adapted to polymerise a coating which has been applied by the pigment applicator and/or provide a polymerised film or polymerised coating to the article with the pigment such that the pigment can be fixed in place. The combination of the pigment and the plasma coating may be referred to as the first plasma coating.

A second pigment applicator is positioned after the first plasma modules 20 and may be used to provide a subsequent pigment on top of the first plasma coating. The pigment may be applied to the first plasma coating in the same manner as the first pigment applicator, or may be applied with a different pigment application device or method, as the first plasma coating may be used to change the surface to which the pigment is being applied relative to the surface of the article prior to treatment. It will be appreciated that the second pigment applicator may be the functional equivalent and provide the same pigment application as that of the first pigment applicator.

The second pigment applicator may also be used to impart a secondary colourant, a functional pigment, or any other predetermined pigment to the article and/or first coating. The further pigment may then receive a plasma coating thereon, whereby the plasma coating is a second plasma coating applied to the article 1. The second plasma coating may have a thickness which is thinner than the first coating, the same thickness as the first coating, or a greater thickness than the first coating.

A first coating on an article may allow for a second coating to develop or build relatively faster than the first coating, as the first coating may act as a foundation layer to which any additional coating may have a faster deposition rate, particularly when the plasma module is adapted to provide the chemistry for the second coating deposition.

In a further embodiment, the first plasma coating which has been applied to the article may be partially polymerised such that the second pigment applicator may apply pigments which may either react with the partially polymerised coating, or may be partly embedded or penetrate into the partially polymerised coating.

In another embodiment, the system is adapted to apply a pigment and/or coating to a predetermined location of the article, and the second pigment applicator may also be configured to apply a pigment and/or coating to the same predetermined location or a second predetermined location. In this way the system may be adapted to impart a pattern with varying colourants and/or varying functionalities. This may be of particular use in relation to flexible circuits, patterned aesthetics, abrasion resistance, improved gripability or any other predetermined or desired pigment application.

In another application, the pigment applicator may be replaced with a hot melt applicator, which may be adapted to form beads or 3D arrays on the article. A hot melt applicator may be used to melt granules, pigments, pellets, and the like for controlled application of elements to the article. Elements may be used for tactile applications and may have a plasma coating applied thereto after, or the elements may be cured by a plasma treatment. Hot melt elements may be printed onto the article by the hot melt applicator and solidify on said article. The elements may optionally include one or more pigments which are contained within the elements or protrude from the elements.

Elements may be extruded from the hot melt applicator and a fixation to the article may be achieved as the elements solidify. Plasma coatings may be used to assist with the fixation of the elements. Elements may be fixed chemically with the article, or may be a surface bonding wherein a clear interface is present.

Optionally, the system 10 may be adapted to perform batch treatments of articles 1, or a treatment of a single article 1. The system 10 is adapted to apply a coating to an article which comprises a plasma treatment step.

The process for utilising the system may include the application of a pigment, powder, or particle to an article. The terms pigment, powder, particle, and nanoparticle may collectively be referred to as a ‘particulate’, and any reference to the term “pigment” may optionally be replaced with the term “particulate” such that pigment may be read as a broader interpretation within the context of particulates.

In another embodiment, the system may be adapted to apply the particulates to an article in a solution or solvent. The solution or solvent may then be removed from the article, thereby leaving the particulate on the article 1. During removal of the solution or solvent particulates may migrate on the article due to the surface tension of solutions or solvents being removed from the article. Heating, particularly a heated air flow or infra-red heating, may be used to evaporate solutions or solvents on the article 1 and retain particulates generally where they have been applied, or urge the particulates into recesses on the article 1. This may prevent agglomeration or particulate migration to undesired regions of the article 1, and thereby improve the distribution of the particulates across the article 1.

Articles may have a natural surface charge which may be altered temporarily to encourage particulate attraction to one or more desired surfaces of the article 1. Changing the surface attraction may be achieved by an electrostatic field, a magnetic field, a charge being imparted to the article, or by a friction to create negative charge on a desired surface of the article. Altering the surface charge is preferably temporary, yet may last for at least a portion to the entire treatment of the article such that pigments may be temporarily fixed in place before a plasma polymerised coating is formed around and/or on the pigments.

The pigment applicator of the system may include one or more different mechanisms for the dispersion and application of pigments on an article 1. Pigments are preferably stored in a reservoir or hopper and directed through a manifold to the applicator head. The pigments may then be distributed to the article in a number of different methods.

The method of dispersion may be dependent on whether the pigment is within a suspension or a dry pigment is to be provided to the article. The distribution methods may include a carrier fluid, such as a gas or liquid, which can be used to transport the pigment to the article. Gases which may be used to carry the pigments may preferably be inert gases, or gases which may be advantageous for a plasma polymerisation or forming a reactive species within the plasma generated by the plasma treatment module 20.

Optionally, the pigment applicator may form part of the plasma treatment module 20 whereby the pigment applicator may pass the pigment and the carrier fluid through the plasma before being deposited onto the article. During the application of pigment in this manner, the pigment may be excited and bonded with a binder, chemistry, precursor, monomer, or another pigment. As the pigment and the carrier fluid are passed from the pigment applicator outlets to the plasma region, excitation and/or bonding of the pigment with a precursor, chemistry or monomer may be achieved.

It will be appreciated that the carrier fluid may not form part of the reaction within the plasma region as part of the desired polymerisation process, and may be used to react species within the plasma region which are not desired to be deposited onto the article 1. Any by-products produced by the system may be gases or particulates which can be directed to extraction locations within the system chamber 15 and recycled or disposed of.

In one embodiment, the pigment applicator is adapted to use electrostatic means to apply a powder to an article. In this configuration, the pigments supplied to the pigment applicator are subjected to an electric current and charged. The charged particles are then ejected or distributed from one or more outlets which are directed to face an article. The pigment may then be attracted to the article which may then be fixed in place by a subsequent plasma coating. The pigments which are supplied for this method can be a mix of pigments, whereby some pigments provide a colourant, and others are for functional purposes. Functional purposes may be an end functionality imparted to the article, or may be a functionality to assist with the electrostatic coating method of the pigment applicator.

To assist with the coating method, it may be desirable to also impart a charge to the article, or around the article, to improve the attraction of the pigment. This may be done by applying a charge to the article, or providing an electric, static, or electrostatic field around the article which can urge the attraction to the article. A bed or chargeable element may be provided relatively below the article to impart the desired charge in the region of the article. It may be preferred that the article is grounded or has an opposite charge to that of the charge applied to the pigments.

Pigment coatings may utilise pigments formed from polymeric resins which may be combined with at least one curative, levelling agent, colourant, flow modifier, or other additives which impart a functional aspect to the coating. Combination of these ingredients may be achieved by melting the composition, cooling the melt and subsequently grinding the cooled combination into a powder which may be referred to as a pigment herein. This type of pigment may be ground to any desired size, and preferably includes a binder which may be polymerised or reacted with exposure to a plasma region.

Unlike conventional powder coating systems, the system 10 and method herein may preferably utilise a plasma treatment step in the chamber 15, 15B. A plasma treatment module may be used to cure, react, melt, or otherwise fix the pigments to the article, whereby the colourant of the pigment is visible after the plasma treatment. Optionally, the plasma treatment may be a plasma coating step whereby a further chemistry is applied to the article which has received a pigment coating. The further chemistry many be a chemistry suitable to polymerise with exposure to a desired plasma state, such as a glow plasma, or may be adapted to react with at least one additive or curative of the pigment applied in the electrostatic application step when exposed to plasma.

Optionally, after a plasma treatment or coating step, the article and the coating thereon may be applied to at least one post-treatment step, which may include at least one of a cooling step, a heating step, an abrasion step, laser exposure, a sintering step, an electromagnetic radiation, and/or a light exposure step to finish the coating on the article. These post-treatments may be effected within a chamber which is the same chamber 15 as the plasma treatment and/or plasma coating, or may be within a separate chamber 15C.

Outputs for the electrostatic means may be in the range of 5 kV to 100 kV, however in some configurations the output voltages may be reduced for different pigment types or sizes.

Fluid pressure for the electrostatic pigment applicator may be in the range of 0.5 CFM to 20 CFM, depending on the pigment size, and the distance to the article. Optionally, a series of discrete application devices may be used across the width of each applicator 18 which may be used to selectively apply pigment across the article 1. The fluids used to urge the pigments from the pigment applicator may be any predetermined gas which can be compressed. Such fluids may be the same as the plasma gases used in the plasma treatment step of the system, or may be a fluid which can form a reactive species for reaction within the plasma region. For example, the fluid may be nitrogen, air, oxygen, carbon dioxide, or any other desired gas which may be reactive. Alternatively, the gas used may be inert, such as helium, argon, neon, xenon and the like. If the inert gas is different than the plasma gas, the inert gas supplied during the pigment application step may be used to improve the ease of plasma generation in the plasma treatment step as inert gases may be transported to the plasma region of the plasma module.

Optionally, the article may enter into a fluidised bed whereby a heated article may be passed through a bed of pigments whereby the heat of the article, which may be supplemented by a further heat source local the fluidised bed, is sufficient to melt or react the pigment in the bed and cause adherence to said article before a plasma treatment step.

In yet a further embodiment, the pigment applicators may be adapted to be a 5-axis applicator, or for more complex articles to be treated may be a 6-axis applicator which can apply pigments to an article from any desired direction or from any desired distance. This may be advantageous to control the flow of particles and the thickness of the pigment coating applied.

Stationary heads may generally be preferred for simplicity of treatment of roll-to-roll articles to be treated, however pigment applicators may be adapted to move when a particular effect is desired to be applied to a coating. For example, portions of an article may be free of pigment with an axial movement of the pigment applicator in the width direction.

Moving pigment applicators may have outlets which are relatively smaller than the article to be treated such that overspray or undesired application of pigments can be controlled during movement. The outlets of the pigment applicators may be any predetermined shape, but may preferably have a circular, ovoid or rounded shape to assist with controlled application of pigment.

A spray curtain or injector curtain may be used as part of the pigment application process and may be referred to as a spray applicator. The spray applicator may be formed from one or more spray nozzles or spraying devices. Spray applicators may have a series of outlets aligned in a predetermined manner such that a curtain or wall of pigment application spray, aerosol, vapour, or any other propellent may be ejected from the spray applicator. Fluids and/or pigments from the spray applicator may be in the temperature range of around −50° C. to 280° C. at the time of ejection from the outlets. Temperature ranges may be restricted based on the article to be treated to ensure that the article is not damaged during processing. While the temperatures at the time of ejection may be greater than or less than ambient temperature, the fluids and/or pigments may cool or warm by the time they interact with the article 1 which may allow for temperatures of fluids and/or pigments which are higher or lower than acceptable temperature tolerances of the article being treated. For example, the melting point of polyester is around 260° C., and the ejection temperature of a fluid and/or pigment from the spray applicator may be around 280° C., however the distance between the outlet of the spray applicator to the polyester article may allow for a desired cooling to take place and bring the temperature of the fluid and/or pigment to a temperature less than the melting temperature of the polyester article.

It will be appreciated that the system will be adapted to limit temperature minimums and maximums of the pigment applicator to prevent damage to a selected article type before processing. Alternatively, the system may have an article inspection identifier which may automatically detect the material to be treated and impose dynamic temperature controls.

Further, the system may be adapted to determine the thickness of an article, such as a substrate, and adjust the relative location of a surface to be treated with respect to at least one of the pigment applicator and/or the plasma module and/or the post-treatment module. Determination of thicknesses of the article to be treated may be done with the use of a virtual measurement wherein a virtual box may be generated to determine the height profile of the article to be treated. Such a system will utilise camera systems which can assess at least one of the height, width, topography, and porosity of the article. Using these measurements the compression of entry rollers may be varied, or modified to allow for a desired processing speed while reducing undesired tension on the article 1.

Purification of gases may be desired when chamber gases include one or more plasma gases which are recoverable. For example, argon gas may be desired to be collected and reused, and by-product contaminants may be removed from the collected gas such that the gas may be returned to the module 20 for further use at a purity of around 95% or greater.

Electrostatic transfer drum (ETD) systems may be used with the system 10. These ETDs may be used to impart one or more colours in any predetermined pattern, array or shape. It may be preferred that the ETD is used to transfer one or more colours across substantially the width of the article to be treated, however some designs or patterns may alternatively be restricted to a predetermined image to be reproduced.

An image to be reproduced with an ETD may be projected onto a sensitised surface of a xerographic plate to form an electrostatic latent image thereon. Thereafter, the latent image can be developed to form a xerographic powder image, corresponding to the latent image on the plate surface. In this way one or more colours may be imparted or transferred, a number of colours may be imparted or transferred, and any desired pattern or shape may be imparted or transferred. The powder image can subsequently be electrostatically transferred to a support surface to which it may be fixed by a fusing device whereby the powder image is transferred to the article 1.

An energisation device, or lamp assembly, may be positioned and be directed towards a xerographic plate and/or the article 1. The energisation device may have a plurality of individual lamps wherein the energisation of the lamps can impart an image with associated colours to expose a photosensitive surface of a xerographic plate at the exposure section, the plate may be a flexible photoconductive belt assembly. The photoconductive belt assembly may be mounted such that light-imaging rays of an original or desired image to be imparted are successively flashed upon the surface of the belt. The belt structure preferably comprises a material which may be sensitised before exposure to the light by a corona generator device or other charge imparting device.

The exposure of the belt surface to the light image discharges the photoconductive layer in the areas struck by light, whereby an electrostatic latent image can remain on the belt. As the belt surface continues its movement, the latent electrostatic images pass through a developing station. A developing station may comprise one or more devices comprising a colour developing material, which may be used to selectively develop electrostatic images. The successively developed electrostatic images can then be transported by the belt to a transfer station where the transfer onto the article is achieved. After the transfer of the image on the belt to the article, the article with the image can then be treated with a plasma, or have a plasma polymerised coating applied thereto. A treatment with plasma may also allow for a plasma polymerised coating to be formed on the article 1.

In another embodiment, the article 1 may be transported into a fuser assembly wherein the transferred powder image on the article 1 is permanently affixed to said article 1. After fusing, white-light may be used to expose the image before being transported to the module 20 for a plasma treatment or plasma coating. It will be appreciated that images may include one or more colourants which are transferred to the article 1 during processing to impart the desired colourant to the article. This may be of particular value in relation to printing on an article, or applying a generally uniform colour or pattern to an article 1.

Devices similar to laser printing may also be employed by the system. Using these types of devices static electricity may be used to impart a charge or attractive quality to the article 1 and/or the pigment. Static electricity is simply an electrical charge built up on an insulated object, such as a balloon or your body. Since oppositely charged atoms are attracted to each other, objects with opposite static electricity fields cling together. A laser printer uses this phenomenon as a sort of “temporary glue.” The core component of this system is the photoreceptor, typically a revolving drum or cylinder. This drum assembly is made out of highly photoconductive material that is discharged by light photons.

In yet a further embodiment, the system 10 may also include a brush device to urge or move pigment on the article 1 into deeper recesses of the article surface. Brush devices may have one or more bristles or elongate elements for moving pigments. Alternatively, the surface of the article may be rubbed, or a textured abutment means may be used to press against a surface of the article and provide some pigment coating redistribution to even the thickness of the coating, and/or redistribute the colourant of the pigment coating before being introduced to the plasma region. Rubbing and textured abutment means will be referred to as brush devices for simplicity, but may be referred to as any of the aforementioned as each may function in a predetermined manner.

Moving larger pigments from the upper regions of an article surface into the recesses of the article surface may also allow for an improved plasma coating to be applied. An improved plasma coating may include a better embedment or fixation of the pigment to be fixed by the plasma coating, or plasma process if the pigment is supplied to the article with a polymerisable binder. For example, larger pigments provided to the article may be urged more readily into any recesses on the article and thereby improve coverage and/or retention of the pigments.

Urging pigment into the recesses may also be used to provide a defined pattern with a darker region and the higher sections of the article coated with the pigment to be relatively free, or entirely free, of the pigment. By using this method it may be possible to provide pigment primarily to recesses of the article and thereby leave the upper surface region of the article generally uncoated by pigment. This may also be advantageous when applying two or more pigments as this may allow for control over colouration in recesses and/or at the upper surface of the article.

Brush devices can be used to form a seal or a partial seal with the article which may deduce the ingress of pigments from the coating chamber of the system to the plasma treatment chamber of the system.

If the coating chamber and the plasma chamber are the same chamber, the brush device may be used to divert excess pigment and/or pigment solution from the surface of the article into a collection reservoir. Pigments and/or solution from the collection reservoir may be recycled or disposed of if there are contaminants or cross colouration from multiple different coloured pigments. Fluid streams or fluid jets may optionally be used to urge pigments from a recirculation or recycling flow such that they can be removed from the system or collected for disposal.

In yet a further embodiment, the system 10 may utilise a duster or a sieve for an even distribution for the particles onto the article. The duster or sieve may be used to apply pigments which are of a predetermined size or smaller onto an article. The duster or sieve pigment applicator may be positioned relatively above an article such that a gravity application may occur. In another embodiment, the system may use a flow of fluid to direct pigments falling from the sieve onto the article to be treated with at least one of a pigment and/or a plasma polymerised coating. Pigments which are not of a desirable size may be ball milled or ground down after collection to be sufficient for a further production process. More than one sieve or duster may be used to distribute pigments or filtrate or separate pigments which may be desired for an application method.

Optionally, the system may be adapted to distribute larger pigments to an article first, followed by smaller pigments after the application of the larger pigments. This may be of particular advantage in relation to pigment fixation as larger pigments may be used to form a foundation with the article, and a plasma coating may be provided to bond or fix these pigments to the article, while allowing for smaller pigments to be applied after which may be fixed by another plasma polymerised coating or at least partially embedded within the first plasma polymerised coating. This may allow for the largest pigments to be more fully embedded and as the coating or binder for the pigment grows the smaller pigments can be added such that the upper surface of the coating formed may be relatively more even.

Dusting pigments onto the article may also allow for a dry process to distribute pigments which may allow for an easier collection of unused pigments by the extraction location.

Another method for distribution for particles may include a spray nozzle. A spray nozzle may have a supply of fluids to entrain, or urge a chemistry from an outlet. The spray nozzle may be a hydraulic nozzle with a pressure range of 0.8-1.4 bar, or a pulse width modulation (PWM) nozzle, or an atomiser with a pressure range of 0.8-1.2 bar pressure for the dispersion or other medium in which the particles are dispersed, suspended, or otherwise dissolved within a solvent. In other embodiments the pressure of the PWM or atomiser nozzles may be in the range of 0.2 bar to 3 bar. Spray nozzle outlets can be used to dose or provide controlled release of fluids to an article 1. In some embodiments the fluids may be a dispersion containing at least one pigment type. Dispersions may be aerosolised, evaporated, or vaporised and may carry the pigment in droplets and may be ejected from the nozzle. For aerosols, pigments of a predetermined size based on the droplet size of the aerosol may be used to only apply pigments of a predetermined size or lower as larger pigments may not be carried by aerosol droplets below a certain size. This may be one method for sieving or pigment filtering by adjusting the aerosol droplet size. This may be achieved by altering the temperature, pressure, or geometries during aerosolization, for example. Other aerosol droplet control methods may also be used as known in the art for aerosolization.

The axial velocity of the liquid leaving the spray nozzle may be in the range of 15 m/s to approximately 160 m/s, while the liquid is approximately at 1 atmosphere pressure and the temperature of the liquid may be in the range of 15° C. to 30° C. In some embodiments the ejection of the liquid from the spray nozzle may be higher than 160 m/s, however this may be more desirable for thicker articles to be dyed, or articles which have a functional aspect which may repel liquids from the spray nozzle. Velocities may also be altered to increase or decrease pigment leaving the spray nozzle. In some embodiments, the velocity of the liquid may be increased to reduce the pigment. The velocity of the liquid may vary throughout the spray, however the higher the velocity of the liquid at the time of injection the deeper the expected penetration into a porous article, or an article which is a textile. Deeper penetration may assist with the colouration of more than one side of a surface of an article, if this is desired. Further, a single side liquid ejection may allow for the application of one pigment or colourant to a single side of an article 1.

In yet a further embodiment, the spray applicators within the system These applicators may be all of the same variant, or may be a mixture of one or more types to allow for a desired application of pigment or dispersion. Air atomising nozzles or hydraulic atomising nozzles may be utilised for application of a pigment. The pigment may be within a dispersion, or may be applied within a gel, or may be applied as a dry or relatively dry pigment. Binders may be used to temporarily bind, fix or attract the pigment to the surface of an article 1. It will be appreciated that the use of a dry pigment may be referred to herein as application of a fluid in some embodiments, however this fluid may be a dry fluid.

Pulse width modulation nozzles may allow for fluid delivery to be modified such that the intensity of colour applied may be varied. Colour intensity may be modified in any desired manner such that a consistent colour application may be applied to an article 1, or there may be a pulsed, wavey, transition or other desired effect imparted to the article. Effects imparted may be optical or patterned effects. The throughput of the dispersion or solution may be controlled by the system to allow for increased or reduced volumes to be provided to an article 1.

The spraying nozzles may propel the dispersion or solution with the pigment towards the article at a predetermined distance and/or predetermined velocity. The pressure of the nozzles or the velocity of the spray may allow for a level of depth penetration into an article, such as a porous article. Depth of penetration may be particularly useful for colourants applied to a textile, woven substrate, or non-woven substrate. The depth of the penetration may be at least 20% of the thickness of the article. It will be appreciated that the depth of penetration may also be limited to 50% or less such that a first side of an article 1 may be treated with a first colourant and a second side an article may be treated with a second colourant. Alternatively, the depth of the colourants may be predetermined to impart a desired effect on the article, and may optionally be applied to one or more sides of the article 1. For example, a dispersion with a colourant pigment may be applied to an article 1 at a depth of 50% of the thickness of the article, and a second dispersion may be applied at a lower or greater depth to impart a desired colour transition, colour change, or colour effect such as a pearlescence, shine or lustre.

Spray applicators may be a removable cassette within the system 10, such that servicing or cleaning may be conducted. Cassette spray applicators can be also loaded with a desired dispersion, paste, colourant or other material to be sprayed to an article 1.

Particles may be distributed in solvent or solution, such as ethanol or water, or may utilise a chemistry which may act as a binder or a portion of a binder which reacts with a further chemistry supplied during the plasma polymerisation stage.

Solvent inks may be dispersed by the system onto the article, and may comprise a pigment is carried by an alcohol and/or oils. In some configurations the pigments may alternatively be carried by water, such as for aqueous inks, or another liquid suitable to disperse the ink. Solvent inks and aqueous inks may be evaporated and leave a colourant behind on the article 1.

If the system is adapted to use a dispersion or other liquid to apply the pigment to the article 1, the system may also include a drying segment, which may have a heater. The drying segment may be positioned between the spray applicator and the plasma modules such that the article may be dried, or otherwise have at least a potion of the dispersion, solvent or other liquids removed before being treated by a plasma module, or before having a plasma coating applied thereto to fix the pigments in place. Heaters of the drying segment will be adapted to remove a minimum volume of liquid from the article before being treated by a module 20 of the system 10. It will be appreciated that the liquids applied by the pigment applicator are preferably removed before being exposed to a plasma as the liquids applied by the pigment applicator are preferably not adapted to be polymerised within the plasma region.

Heaters which may have particular utility with the system may include ceramic heaters, or glass lamp heaters wherein radiant heat may be used to evaporate solvents or other liquids from the article before being treated with plasma or having a plasma coating applied. These types of heaters are corrosion resistant and may also operate within a plasma gas environment or operate within an environment with evaporated volatiles. The heating elements may have at least one extraction region located adjacent to the heater adapted to remove moisture or evaporated material from the system 10. Extraction regions may have a pressure differential to encourage movement of evaporated liquids or may otherwise have an active entrainment to remove fluids from internal the system. Optionally, the fluids collected from the extraction device may be passed through a recirculation system wherein a cryotrap or other liquid removal system may be used to condense out the evaporated fluids captured with the extraction.

Heaters installed into the system may optionally be fitted with a heater shroud which may insulate other components of the system 10. Further, the heater shroud may have the extraction region therein such that the shroud encloses the heater and the extraction of the evaporated liquids. A gap below the shroud may allow for the article to pass under and is sized to minimise evaporated liquids from entering into the chamber area adjacent the heater shroud.

As the article passes from under the heater shroud, the article may be cooled by the plasma gases within the chamber and be of a desired temperature before entering into the plasma region. This may be beneficial for certain types of coatings as the temperature of the article at eth time of plasma coating may be desired to be in the range of −10° C. to 40° C.

In yet another embodiment, the system 10 may use a padder system to apply a pigment within a solution or solvent to an article 1. The padder system may have an intake roller and one or more mercerizing rollers. The first two mercerizing rollers forming the entry pair are designed as an air squeegee; their gap essentially is located in the liquid level of the mercerizing liquor. In this manner, when the article, especially hose, passes from the air into the liquor, the air is removed from the article and a better effect of the liquor on the ware is made possible. The last mercerizing roller rests against the next dye padder roller, and the mercerizing rollers dip at least partially and intermittently into the mercerizing liquid in the mercerization container. The dye padder roller is designed as a drive roller and a squeezing roller is mounted above it. The squeezing roller can be lifted off of the drive roller and is supported in rotatable manner for instance on a pivotal arm, the lifting motion off of the drive roller being effected, for instance, by adjusting a lifting means designed as a pneumatic cylinder. Furthermore, the spray nozzles are mounted approximately at the level of the squeezing roller. The ware is prewashed by means of these nozzles during the initially mentioned rewinding of the ware for the intermittent mode. A cooling vessel and a pumping means are further indicated underneath the mercerizing container, whereby the initially described intermittent mercerizing process is carried out.

Optionally, the pigment, which may be a colourant, may be provided to the article in the form of a foam. A foam may be created from the dispersion of pigment within a liquid or other medium. Foams may expand from an injection nozzle and the foam may expand to cover at least a portion of the article to be treated. Foams may also be used to provide a more even distribution of a pigment within the foam before the foam contracts and leaves a pigment on the article 1. Foams applied to an article may also be urged in a desired direction by restricting the volume of the chamber leading towards any airlock or rollers. This may allow for a desired or uniform foam thickness on the article before plasma treatment.

In yet another embodiment, the system may be adapted to apply a pigment or powder to a substrate. Pigments applied to a substrate may be applied using at least one of the following methods; electrostatic powder coating (or pigment coating) spraying methods, drum transferring methods, dusting methods, spray nozzle methods, padding methods, foam applicator methods, anilox roller methods, and printing methods. Other methods may also be applicable and may be described herein.

Pigments and powders suitable for use with the present disclosure may be of a size in the range of 1 nm to 900 micron. Preferably, any pigment or powder utilised will be in the range of 10 nm to 1000 nm in thickness, or may be in the range of 200 nm to 1000 nm, or may be in the range of 400 nm to 600 nm, or in some cases may be in the range of 1 nm to 200 nm on average in size. When referring to pigment size, it will be appreciated that the size may be of a material in a single plane only, and that pigments, powders and particles may have plate-like geometries or other desired geometries for specific applications.

For example, the use of mica particles or pigments may be used which may have a 1-10 nm thickness, but have a width which is at least one magnitude greater than the thickness. Plate-like pigments or particles may be arranged in a randomised orientation when applied to the substrate, or may be encouraged to be relatively more parallel to the surface of the substrate.

System colour selection may be similar to conventional printing methods which may employ a monochrome to hexachrome colour method, or in some embodiments a heptachrome colour method may be used. Pigments, dyes, or other colourants may be used to provide each chromatic for the method used. Colourants may be applied in one or more application processes and individual pigment applicators may be used to provide distinct colours, or one or more pigment applicators may be used to provide one or more colourants as desired.

In another embodiment, pigments which are colour imparting pigments may be provided with a CMYK (cyan, magenta, yellow and black) colour array to an article. CMYK colouration of an article have use halftoning or screening which allows for less than full saturation of the primary colours. Using this method may use tiny dots of each primary colours printed in a predetermined manner which imparts a desired visual colourant.

The system 10 may be adapted to allow for a premixing of colourant pigments such that a desired colourant is formed for application to an article 1. In another embodiment, the incremental application of pigment may be desired, wherein a first pigment application module may be used to apply a fix pigment, or pigment mixture, to an article 1, and a second pigment applicator may be used to apply a second pigment or pigment mixture to the article thereafter. More than two pigment applicators may be used in this way, and each may be adapted to apply one or more predetermined pigments to the article. In this way a desired pigment can be imparted which may have a desired colourant from the application of multiple pigment colourants. In a further embodiment, a pigment applicator may be provided which corresponds to one of the colourants for a CMYK process, such that four pigment applicators are used in the process. Similarly, any number of pigment applicators may be provided within the system with each applicator corresponding to a distinct colourant for a chromatic process, from a monochrome process to a heptachrome process. In addition to any number of applicators generally required for a predetermined chromatic process, the system 10 may further include a white pigment applicator in addition to any other pigment applicators. This is to say that for a heptachrome configuration, around eight pigment applicators 18 may be desired. More than one pigment applicator may be directed to the same location of an article at any one time such that application by two or more spray applicators can occur simultaneously. It will be appreciated that the pigment applicators may be spray applicators.

Colourants may be controlled by controlling loading rate of the pigment to an article, or may be controlled by the inclusion of white pigment colourants or lighter tone pigment colourants which may augment or change the intensity or overall visual colourants applied to the article. Each of the colourants applied to an article may be applied in a predetermined volume or by weight. The system controller 11 may be configured to dose correct volumes or loadings for a desired resultant colourant on the article.

In yet a further method, the system may also use spot colour printing wherein specific colourants are used to generate colours on an article 1. A spot colour or solid colour may be any colour generated by an ink, pigment, or other colourant, which may be pure or mixed, that is applied to an article in a single run, whereas a process colour is produced by printing or applying a series of dots of different colours to effect a desired colour which can be perceived by a viewer. Dots may be applied as pigments which may be printed, sprayed, or deposited onto the article 1. CMYKOG methods may utilise a similar colour array as that of CMYK, but further include orange and green colourants which can be used to provide a more defined and accurate colour relative to CMYK methods.

Optionally, Pantone™ colour systems may be used which is a six colour hexachrome system CMYKOG which may expand the gamut of the available colours greatly. However, it will be appreciated that other hexachrome methods may also be used, such as the CcMm YK colouration methods, which further include light magenta and light cyan colourants. Light, saturated colours often cannot be created with CMYK, and light colours in general may make visible the halftone pattern. Using a CcMmYK process, with the addition of light cyan and magenta inks to CMYK, can solve these problems.

While some examples of colour systems have been discussed, it will be appreciated that the system may be adapted to utilise one or more other standardised or common, colour systems within industry. For example, the system may be configured to use at least one of; Pantone™, Toyo™, DIC™ Colour System Guide, ANPA™, GCMI™, HKS™ (Hostmann-Steinberg Druckfarben, Kast, Ehinger Druckfarben and H. Schmincke & Co.), and RAL™.

RAL CLASSIC™ colour systems may be primarily used for powder coating colourants, and may have a desired classification method for a range of industries. It will be appreciated that as each system is designed independently, colours from a first colourant system may not be possible to form with a second colourant system. However, the system may be adapted to accommodate pigments or other colourants which can accommodate for more than one colourant system.

As pigments may be desired infrequently, or some pigments used less than other pigments, the system may have one or more devices which can agitate, mix, move, or sonicate the pigment before application to an article 1. This may allow for a more consistent final colourant to be applied to an article 1.

Pigments may be optically assessed for an average colour of a pigment and the system 10 may be adapted to dynamically adjust the final colourant by mixing ratios of pigments in a predetermined manner. Mixing these pigment colourants may be similar to conventional printing methods.

Similar to conventional laser printing devices, the pigment applicator may be adapted to add colourant in a predetermined manner to create a predetermined colour pattern or image. A plurality of toner and developer units may be mounted on a rotating shaft or wheel. In this manner the printer may then apply an electrostatic image for one colour and aligns the toner into the desired position. The colour may then be applied and the next colour required can be moved into position to repeat the process as needed.

Alternatively, all colourants may be added to a plate before transferring the image on the article. Some methods of applying pigments to the article may be limited based on the geometry, thickness, or topography of the article.

Natural pigments may be plant pigments chlorophylls, anthocyanins, carotenoids, and betalains. Natural pigments may also include biological pigments selected from the following group: Heme/porphyrin-based, chlorophyll, bilirubin, hemocyanin, hemoglobin, myoglobin, light-emitting: luciferin, Hematochromes (algal pigments, mixes of carotenoids and their derivates, carotenes, alpha and beta carotene, lycopene, rhodopsin, Xanthophylls, canthaxanthin, zeaxanthin, lutein, proteinaceous, phytochrome, phycobiliproteins, psittacofulvins, turacin and turacoverdin, melanin, urochrome, and flavonoids. In addition, algae pigments may also be suitable for inclusion within a plasma coating. These pigments may include; Chlorophyll a, b pigments and Chlorophyll c, -Ficobiliproteins, -Phycoerythrin, -Xantophyll, and Fucoxantin pigments. Biosynthetic dyes may also be used, whereby bacteria, sugars or other organic matter may be used to generate a desired colourant or pigment.

Some pigments may be added to the coating which have a selective colour absorption. Such pigments may be synthesised or derived from plant pigments, flower pigments and biological structure pigments such as chromatophores. In addition, polymerisable chemistry, monomers, and precursors may also be generated from a biomass source for making a film or plasma polymerised coating

Bioplastic precursors may be sourced from biomass such as vegetable fats and oils, corn starch, straw, woodchips, sawdust, recycled food waste, seaweed and the like. Some bioplastic precursors are obtained by processing directly from natural biopolymers including polysaccharides (such as; starch, cellulose, chitosan and alginate) and proteins (such as; soy protein, gluten and gelatin), while others are chemically synthesised from sugar derivatives (such as; lactic acid) and lipids (oils and fats) from either plants or animals, or biologically generated by fermentation of sugars or lipids. Materials such as biobased polyethylene terephthalate, biobased polyethylene and degradable bioplastics, such as polylactic acid, polybutylene succinate, or polyhydroxyalkanoates may be produced from the above precursors or other biomass sources. These materials may be of particular use as monomers, precursors or plasma polymerisable coatings.

Polysaccharide-based bioplastics may be suitable for application to an article with the system, with such bioplastics including; starch-based plastics, cellulose-based plastics, chitosan and alginate. Chitosan may be of particular advantage as pigments and other biopolymers may be easily incorporated in a polymer formed therefrom and may be used in a wide range of packaging applications.

Bioplastics derived from starch will have properties which are dependent on its amylose/amylopectin ratio. For mechanical properties the pigment may include a higher ratio of amylose starch relative to amylopectin which may be advantageous. Mechanical property ratios are known within bioplastics manufacturing and are incorporated herein. Starch-based bioplastics may optionally be mixed or blended with biodegradable polyesters to produce starch/polylactic acid, starch/polycaprolactone or starch/polybutylene adipate-co-terephthalate (commonly referred to as Ecoflex™). However, while the above starch bioplastics may be formed with the system, the system may have particular advantage in forming starch-based films which may be suitable for food packaging purposes, wrappings, packaging, papers, and composting items. These films may be formed from pigments including starch and thermoplastic polymers.

Another type of plastic which may be formed during a plasma polymerisation process may be protein-based plastics. These plastics may be formed from gluten, casein and soy bases. Aliphatic biopolyesters biopolyesters are mainly polyhydroxyalkanoates (PHAs) like the poly-3-hydroxybutyrate (PHB), polyhydroxyvalerate (PHV) and polyhydroxyhexanoate (PHH). In addition, polylactic acid (PLA) may be produced readily in the form of pigments, powders and granules. Using PLA bioplastics may allow for the formation of films, fibres, and packaging materials, for example. Polyhydroxyalkanoates are linear polyesters produced in nature by bacterial fermentation of sugar or lipids. Polyhydroxyalkanoates monomers may be readily used to form articles suitable for medical purposes. Polyamide 11, Polyhydroxyurethanes, lipid derived polymers, and other biomonomers and/or bioprecursors may be used with the system and may be provided in liquid or pigment form based on the application method.

Bio-derived polyethylene may be formed from ethylene monomer which can be derived from ethanol. Other alcohols may also be suitable to form a polymer when exposed to plasma. This may be of particular advantage when it is desired to carry a pigment in an aerosol or vapour, as the liquid portion of the aerosol or vapour may be an ethanol or ethylene monomer.

Generally, there are a number of categories of pigments which include: white pigments, coloured pigments, black pigments and special pigments. These pigments may be derived from natural sources or synthesised, or a combination of both. Particles which are insoluble in the application medium (varnishes, synthetic materials, printing inks, cosmetic formulations and construction materials) may also be used for forming a portion of a coating.

White pigments may impart a colour to an article 1 by diffuse reflection of light. Absorption pigments impart a colour through the absorption of light (additional diffuse reflection). Metallic pigments may create a shine from the reflection of light, and can be metal pigments. Special effect pigments, such as pearlescent pigments, may impart a colour, shine and/or interference effect through reflection and refraction of light (interference). These pigments properties may also be augmented by the plasma coating above and/or below the pigment to achieve a desired effect.

Special pigments may include transparent and functional pigments as well as effect pigments. Effect pigments may further be reduced to two subcategories which may include metal effect pigments and special effect pigments. Metal effect pigments may preferably comprise aluminium and/or copper-zinc alloys, with special effect pigments being used for pearlescent and interference pigments.

While pigments herein may be referred to as having a generally uniform diameter or uniform size, it will be appreciated that this is for simplicity and the surface of the pigment will generally be irregular or have an undulating surface from the production method. Pigment sizes suitable for the present application method and system may be in the range of 0.1 μm and 200 μm in diameter. However, effect pigments may be larger than pigments used for mere colourant. Effect pigments may have a size or diameter of between 5 μm to 100 μm, with these pigments having additional properties of being transparent, semi-transparent or light impermeable platelet-shaped particles. Other effects may also be imparted by pigments which may include one or more functional properties such as; magnetic, anti-corrosion, luminescent, antimicrobial, antiviral, flame retardant, hydrophobic, hydrophilic, self-cleaning, and oleophobic properties.

Effect pigments may generally be split into two categories which are metal effect pigments and special effect pigments. Both metal effect pigments and special effect pigments produce lustrous effects in the pigmented surfaces which is from the reflection of light onto the pigment. In the special effect pigments pearlescence and interference are created by the division of the light from the light rays falling on the pigment surface because only a portion of the light is reflected while another part of the light penetrates into the transparent or semi-transparent particles and onto the deeper lying boundary layers from where it is reflected back. This results in the overlaying of light waves which, depending on their wavelength, are either intensified or diminished, which may be an interference.

Various types of coloured interference phenomena combined with gloss effects can be created by selecting pigments of metal oxide with respect to the refractive index of the binder (plasma polymerised coating) as well as the thickness of the plasma polymerised coating. The thicknesses of these coatings may be desired to be in the range of 5 nm to around 500 nm. Variations in the size of pigment particles, it may be possible to achieve varying effects from silk-matt to a very glossy transparent to a more opaque finish. This type of pigment application may use a sieve pigment application method, whereby pigment sizes are controlled, or may use a combination of laminations of pigment application and plasma polymerised coatings to achieve the desired effect.

Pigments may be selected with respect to its refractivity with respect to the thickness of the plasma polymerised coating, and/or the opacity of the plasma polymerised coating. Assessment of these properties may allow for bright interference colours or interference pigments to be applied to an article. A metallic sheen is, by contrast, produced by the simple reflection of light from metal platelets. The interactions using visible light that are fundamental to special effect pigments and metallic effect pigments.

Any predetermined pigments may be used within the plasma polymerised coating. At least one of a colourant or a functional pigment can be included within a plasma polymerised coating.

In yet a further embodiment, the pigment is provided at the time of polymerisation or before polymerisation to assist with coating formation and deposition rate. The pigment at the surface may allow for an improved coating thickness and/or coating adhesion due to the polymerised chemistry being more readily captured at the surface of an article. This is of particular advantage when chemistry, monomer or a precursor is provided to an article via the plasma region.

In another embodiment, the pigment size may be in the range of 10 nm to 1000 nm, however more specific particle sizes may be desired based on the optical effects of the pigment in a desired range. For example, some pigments may be desired to be in the range of 300-450 nm to provide for a desired lustre, opacity, transparency, or embedding within the coating.

There are a number of natural pigments which may be suitable for dyeing purposes which can be subjected to a plasma coating or plasma treatment step. These pigments may be embedded within the coating applied during a plasma polymerisation step, or a coating which is polymerised in a post-plasma polymerisation step. Natural pigments may be derived from natural sources which may include, but are not limited to; plants roots, nuts, fruits, vegetables, and flowers. Carbon captured pigments may also be used which have been captured from industrial emissions or other CO₂ emission sources.

Other pigments may be derived from recycled materials, which may include recycled garment pigments, recycled plastics, recycled packaging and recycled glass. Other pigments which are derived from recycled applications may also be used.

In a further embodiment, mica may be used as the pigment to be included within a coating. Mica is generally a naturally occurring mineral that can incorporate a desired shine to a colour. Further, mica pigments may be provided in any predetermined size or desired colour, and are generally planar or plate-like in appearance. Mica pigments may be provided in a size range of 10 μm to 100 μm across the surface with the thickness being in the range of 200 nm to 10 μm.

It may be desirable to include mica pigments as plasma coatings can be in the range of 100 nm to 500 μm in thickness, depending on the treatment time and parameters. Therefore, the thickness of the mica may allow for mica to be laid relatively parallel with the surface of an article to be coated and be relatively encapsulated or mostly embedded within the plasma polymerised coating.

Generally, mica pigments may be selected based on their opacity, transparency, and/or lustre. As a guide, mica particle sizes with a size of 15 μm or less may have a low lustre and a higher opacity, sizes of 2-25 μm may have a silky lustre and higher opacity, sizes 10-60 μm may have a pearl-like lustre with moderate to medium opacity, sizes 10-125 μm may have a shimmering lustre and lower opacity towards transparent, sizes 20-150 μm may have a sparkling lustre and be generally transparent, and sizes 45-500 μm may have a more glittering lustre and may be very transparent. Plasma coatings used to fix these pigments may also impact the lustre or the opacity/transparency of the pigment. For example, the plasma coating may be adapted to reduce the lustre of pigments which have a natural or inherent high lustre, and thereby make the pigments appear more matt in appearance. Additional functionalities may also be imparted by certain pigments which can be embedded, encapsulated or otherwise bonded with a plasma coating.

Other metals and inorganic materials which may be used as pigments may be selected from the following group; titanium, aluminium, zinc, gold, cesium, copper; sulfates of calcium, strontium, barium; zinc sulfide; copper sulfide; titanium dioxide and barium zeolites; mica; talc; kaolin; mullite or silica. In addition, lead or mercury compounds may also have some use depending on the application. The average diameter of the metals deposited may be between 0.01 and 200 microns, preferably in the range 5 to 100 microns.

The textile receiving the metal coating may be inorganic particles having a first coating of a metal or metal compounds and a second coating layer of silica, silicates, borosilicates, aluminosilicates, alumina or mixtures thereof.

The inorganic particles, i.e., core material may be any of the oxides of titanium, aluminium, zinc, copper; calcium, strontium, barium and lead. Optionally as suggested, the materials may be sulfides or sulfates. It is preferred that a near pure metal or a metal alloy can be used to form a pigment for the pathogen disruptive layer. However, it will also be appreciated that other compounds may be used, such as silver nitrate (AgNO₃), or titanium dioxide (TiO₂). Other pigments commonly used in industry including organic and inorganic pigments may also be used if desired.

In one embodiment, pigments may form at least a part of a continuous coating or film which can conform to the general surface topography of the substrate 10. The pigments may be protected, covered, or have a functional coating applied thereto after deposition which can assist with reducing pigments from becoming dislodged from the substrate 10. Properties of functional coatings may include at least one of; flame retardant, UV absorbing, self-cleaning, hydrophobic, hydrophilic, and/or antibacterial. Other functionalisations may also be applied as is known in the art.

In other embodiments, the pigments may suitably be formulated in an appropriate carrier, coating or solvent such as water, methanol, ethanol, acetone, water soluble polymer adhesives, such as polyvinyl acetate (PVA), epoxy resin, polyesters etc, as well as coupling agents, antistatic agents. Solutions of biological materials may also be used such as phosphate buffered saline (PBS), or simulated biological fluid (SBF). The concentration of the pigments in the solution may in the range of from 0.001% (wt) to about 20% (wt). These pigments may then form a coating which can be applied to the substrate 10.

Flame retardants can reduce or inhibit flammability of the textiles by: Reducing the heat generation at combustion process, Reduce flammable volatiles, modify pyrolysis reaction, form intumescent char layer, Release water, Release spices like chlorinated, phosphorus, that act as an inhibitors in gas phase.

Particles which may be suitable for use for flame retardant coatings may include particles selected from the following group; Nano-clays, Zinc-borates, Carbon Nanotubes (CNT), Layered Double Hydroxide (LDH), Polyhedral Oligomeric Silsesquioxane (POSS), silicon dioxide (SiO₂), and metal pigments. Optionally the SiO2 may be nano-size. Any combination of particles may be utilised within a single coating.

Optionally, a coating may be formed from several laminations such that the Suitable nano-clays may be pigments of layered mineral silicates, which may be organized into several classes such as montmorillonite (MMT), and halloysite depending on chemical composition and morphology. Metal pigments may also be metal based pigments or oxides such as titanium dioxide (TiO₂), Zinc Oxide (ZnO), Aluminium oxide (Al₂O₃), for example.

It may be preferred that the thickness of the coating applied is at least 100 nm in thickness. It may be more preferred to select a coating in the range of 100 nm to 100 micron for a fire-retardant treatment or coating.

Preferably the char yield of the substrate is improved with the inclusion of a fire-retardant coating. Coatings may preferably include particles such as fine particles or nano particles. After application of a coating a char yield test preferably exhibits an improvement of at least 1% increased char yield relative to a substrate without said treatment.

The thickness of the coatings may be in the range of 50 nm to 900 micron. It may be more desirable to provide for a coating which is in the range of 150 nm to 900 nm. Preferably, the thickness of the coating to the particle size is in the range of 1:1 to 1:500, and more preferably, the thickness range of 1:2 to 1:200 . It will be appreciated that the average thickness of the coating may be relative to the diameter of the particle within the coating.

It may be preferred that the particles within the coating are generally uniform in diameter or size. It will be appreciated that a distribution of particle sizes may be supplied within the coating, wherein the distribution may comprise a size of particle at in a known size range and the remaining particles are larger or smaller than the known size range. For example, the particles within the coating may have a known particle size of 80% by volume with the remaining 20% of particles being of a size smaller or larger than the known particle size range. In another example, the particles within the coating may have a known particle size of 80% by weight with the remaining 20% of particles being of a size smaller or larger than the known particle size range.

Optionally, the particle coatings applied provide for a flame-retardant coating, or may be used in combination with a flame-retardant coating which has been applied via a chemical vapour deposition process. Preferably, any such deposition process is a plasma enhanced chemical vapour deposition process.

The particles for the flame-retardant coating may be applied in a lamination of the coating, or may be provided uniformly throughout the coating. Particles may be deposited on the surface of the substrate to be coated with a functional coating, or may be provided at the same time as the functional coating is applied to the substrate.

It is preferred that the thickness of the coating, or the build-up of coating at the contact end of the particle, is sufficient to embed the particle or fix the particle in a desired position. The thickness of the coating thickness may extend at least 5% of the height of the particle. Preferably, the particle is encapsulated by the coating.

Precursors that produce functional properties may optionally be used to compliment the pigment selection, or be used to provide a functional binder for the pigments such that other post-processing functionalisation treatments may be avoided or otherwise limited to reduce downstream resource consumption.

Using the system 10, various polymer coatings, polymeric films, pigment coatings, and pigment treatments can be deposited onto an article 1. Non-limiting examples of coating monomers may include at least one monomer elected from the following group; acetylene, ethylene, isoprene, hexamethyldisiloxane (HMDSO), tetraethyloxy silane (TEOS), tetraethyloxy silica, orange oil, tea tree oil, peppermint oil, ethanol, butanol, lactic acid, ethyl acetate, γ-valerolactone, cyrene (dihydrolevoglucosenone), ε-caprolactam, ethyl lactate, stearic acid, candelilla, carnauba wax no. 1 yellow, beeswax, diethyl dimethyl siloxane, 1,3-butadiene, styrene, methyl styrene, tetrafluoroethylene (TFE), methane, ethane, propane, butane, pentane, hexane, cyclohexane, acetylene, ethylene, propylene, benzene, isoprene, hexamethyldisiloxane, tetraethyloxy silane, tetraethyloxy silane, diethyl dimethyl siloxane, 1,3-butadiene m, styrene, methyl methacrylate, tetrafluoroethylene, pyrrole, cyclohexane, 1-hexene, allyl amine, acetylacetone, ethylene oxide, glycidyl methacrylate, acetonitrile, tetrahydrofuran, ethyl acetate, acetic anhydride, aminopropyltrimethylene triethoxyethane triethoxyethanoethoxytethenethoxyethane triethoxyethanoethoxyethane triethoxyethanoethoxyethane triethoxyethanoethoxyethane triethoxyethanoethoxyethane triethoxyethanoethoxyethane triethoxyethanoethoxyethane triethoxyethanoethoxyethane triethoxyethanoethoxyethane triethoxyethanoethoxyethane triethoxyethanoethoxyethane triethoxyethanethoxyethanoethoxyethane triethoxyethanoethoxyethane triethoxyethanoethoxyethane triethoxyethanethoxytriethoxyethanoethoxyethanoethoxy ethanol, tricarbonyl (cyclooctatetraen) iron, dicarbonyl (methylcyclopentadienyl) iron, dimer dicarbonyl (dicyclopentadienyl) iron, cobalt cyclopentadienyl cobaltacetylacetonate, nickel acetylacetonate, dimeti-(2,4-pentan-dionates) gold (III), nickel carbonyl, iron carbonyl, tin acetylacetonate, indium acetylacetonate, indium-tetramethylheptanedionate.

It may be desired to remove any moisture from the article before plasma treatment or applying a plasma coating. Alternatively, an oil may be used to disperse the colourant onto the article, whereby the oil may be polymerised and fixate the colourant to the article.

Oils which may be used are preferably biobased oils, however synthetic oils may also be used if desired. Biobased oils may be essential oils such as an oil selected from the following group; coconut oil, olive oil, sunflower seed oil, shea butter, jojoba oil, almond oil, grapeseed oil, rose hip seed oil, orange oil, allspice oil, ambrette seed absolute amyris oil, angelica root oil, anise oil, anise, star oil, anthopogon oil, atlas cedarwood oil, balsam fir oil, balsam, peru oil, basil oil, basil, holy oil, bay oil, bay laurel oil, beeswax absolute benzoin absolute bergamot oil, bergamot mint oil, black pepper oil, black spruce oil, blood orange oil, blue cypress oil, blue tansy oil, bois de rose oil, boronia absolute bursera graveolens oil, cade oil, cajeput oil, camphor, white oil, cananga oil, cannabis oil, caraway seed oil, cardamom oil, carrot seed oil, cassia oil, catnip oil, cedarwood, atlas oil, cedarwood, virginian oil, chamomile, german oil, chamomile, roman oil, chocolate peppermint oil, cilantro oil, cinnamon oil, cistus oil, citronella oil, clary sage oil, clove bud oil, coffee oil, common sage oil, copaiba balsam oil, coriander oil, cornmint oil, cubeb oil, cumin oil, cypress oil, cypress, blue oil, cypress, japanese oil, cypress, taiwan (formosan) oil, davana oil, dill oil, dalmatian sage oil, douglas fir oil, elemi oil, eucalyptus globulus oil, eucalyptus, lemon oil, eucalyptus radiata oil, fennel oil, fir, balsam oil, fir, douglas oil, fir, siberian oil, fir, silver oil, fragonia oil, frankincense oil, galbanum oil, geranium oil, geranium, rose oil, german chamomile oil, greenland moss oil, ginger oil, goldenrod oil, grapefruit oil, gurjum balsam oil, helichrysum gymnocephalum oil, helichrysum italicum oil, hemlock spruce oil, hemp oil, hinoki oil, hinoki, taiwan oil, ho leaf oil, ho wood oil, holy basil oil, hong kuai oil, hops oil, hyssop oil, ishpingo oil, immortelle oil, japanese cypress oil, jasmine absolute jatamansi oil, java pepper oil, juniper berry oil, kanuka oil, kunzea oil, labdanum oil, ledum oil, laurel leaf oil, lavandin oil, lavender oil, lavender, spike oil, ledum oil, lemon oil, lemon balm oil, lemon eucalyptus oil, lemongrass oil, lemon myrtle oil, lemon tea tree oil, lemon verbena oil, lime oil, linden blossom absolute mandarin oil, manuka oil, marjoram oil, may chang oil, melissa oil, myrrh oil, myrrh, sweet oil, myrtle oil, myrtle, lemon oil, nard oil, neroli oil, niaouli oil, nutmeg oil, oakmoss absolute ocotea oil, olibanum oil, opoponax oil, orange, bitter oil, orange, blood oil, orange, sweet oil, oregano oil, palmarosa oil, palo santo oil, parsley oil, patchouli oil, pepper, black oil, pepper, pink oil, peppermint oil, peppermint, chocolate oil, peru balsam oil, petitgrain oil, pimento berry/leaf oil, pine, pinyon oil, pine, scotch oil, pink pepper oil, plai oil, rambiazina oil, ravensara oil, ravintsara oil, rock rose oil, rhododendron oil, roman chamomile oil, rosalina oil, rose oil,, rose absolute and rose CO₂ extract rosemary oil, rosewood oil, sage, clary oil, sage, common oil, sage, dalmatian oil, sage, spanish oil, sage, white oil, sandalwood oil, saro oil, scotch pine oil, siberian fir oil, silver fir oil, spearmint oil, spike lavender oil, spikenard oil, spruce, hemlock oil, spruce, black oil, star anise oil, sweet myrrh oil, sweet orange oil, tagetes oil, tangerine oil, tansy, blue oil, taiwan hinoki (taiwan cypress) oil, tea tree oil, common oil, tea tree, lemon oil, tea tree, new zealand oil, thyme oil, tobacco absolute tuberose absolute tulsi oil, valerian oil, vanilla absolute and vanilla co2 extract verbena, lemon oil, vetiver oil, violet leaf absolute virginian cedarwood oil, white camphor oil, white fir oil, white sage oil, wintergreen oil, xanthoxylum oil, yarrow oil, ylang ylang oil, yuzu oil, ethanol, butanol, lactic acid, ethyl acetate, γ-valerolactone, cyrene (dihydrolevoglucosenone), ε-caprolactam, ethyl lactate, stearic acid, candelilla, carnauba wax no. 1 yellow, beeswax,. Other essential oils or other bioderived precursors or monomers may also be used if desired.

It is preferred that any biobased oils have a double-bond, or are readily volatile such that they may be evaporated and/or vaporised. Evaporation, aerosolisation, and vaporisation of a chemistry, including biobased oils, may be passed into a plasma region generated by a plasma module 20 and subsequently polymerised. However, if the system is adapted to have an oil applied by the pigment applicator, the oil is preferred to have a double-bond within its structure to allow for polymerisation.

In at least one embodiment, an organic and/or inorganic coating may be applied. Inorganic coating precursors include pure metals, metal salts, oxides, nitrides, carbides, or combinations thereof. In yet another embodiment, the system 10 may allow for various particles to be coated ranging in size from nanometre to micron. Coatings may be deposited by means of precursors that are either in a gaseous or liquid or solid state, but are preferably in a vaporised or aerosol state.

In addition, pigments having a range of sizes from about 10 nm to about 100 nm can be used as components of a larger molecular structure, generally in the range of about 100 nm to 1,000 nm. For example, a pigment may be surface coated to increase its size, be embedded in an acceptable carrier, or it may be entwined or added to other particles, or to other materials, which generate a larger particle. In certain embodiments in which at least one dimension of at least one pigment within a solution of pigments is below 50 nm to 100 nm, the surface of the pigments may be coated with a non-conductive matrix of between 10 nm to 100 nm thick or more in order to increase that dimension or particle to 50 nm to 100 nm or more. This larger size can increase the supply of pigments for deposition onto an article 1.

In yet another embodiment, the pigments have optical absorption qualities of about 10 nm to about 10,000 nm, for example, 100 nm-500 nm. Optionally, the pigments have optical absorption useful for excitation by standard laser devices or other light sources. For example, pigments may be adapted to absorb wavelengths of approximately 755 nm, in the range of approximately 800 nm to 810 nm, or about 1,000 nm to 1,100 nm. Similarly, pigments may also be adapted to absorb intense pulsed light in the range of about 500 nm to 1,200 nm.

The pigments provided herein may generally contain a collection of non-assembled pigments. By “non-assembled” pigments, it is understood that the pigments of said collection are not linked to each other through a physical force or chemical bond, either directly (particle-formula) or indirectly through an intermediary (for example, particle-cell-part, part-protein-part, part-analyte-part). In other embodiments, pigment compositions are assembled in ordered matrices. In particular, said ordered matrices can include any three-dimensional matrix. In some embodiments, only part of the pigments are assembled, for example, 5, 10, 15, 20, 25, 30, 35, 40, 45, 50, 55, 60, 65, 70, 75, 80, 86, 90, 95, 99% or more than 99% of the pigments are assembled in an ordered array. The pigments are assembled by attraction of van der Walls, a London force, a hydrogen bond, a dipole-dipole interaction, or a covalent bond, or a combination thereof.

The microparticles and pigments have an average diameter of around 10 nm to 10 μm, and are distributed on the polymer surface at intervals of 10 nm to 3000 nm, structured as a function of the size of the particles applied.

The plasma polymerised coating formed on the article by the module 20 may be a protective coating which can be used to slow the diffusion of ions from pigments within, or may be a functional layer which provides for at least one functionalisation selected from the following group; flame retardant, UV absorbing, self-cleaning, hydrophobic, hydrophilic, and/or antibacterial. Other functionalisations may also be applied as is known in the art.

The pigment or plasma polymerised coating may be used to provide for at least one of a hydrophobic or hydrophilic functionality. Siloxane chemistry may be used to form a hydrophobic and/or hydrophilic coating on an article 1. Functionality of any such coating may be dependent on the thickness of the coating, the porosity of the article being treated and the pigments applied (if any).

Hydrophilic pigments may generally include transition metal or an oxide or complex thereof. These pigments as described herein may be included within the plasma polymerised coating and may be applied generally at the same time as the plasma coating, or as part of an in-line process.

Some examples of hydrophobic pigments may include; Manganese oxide polystyrene (MnO₂/PS), zinc oxide polystyrene (ZnO/PS) nano-composite, precipitated calcium carbonate, carbon nano-tube structures, silica nano-coating, and siloxane particles. Fluorinated silanes, fluoropolymer coatings, and siloxane coatings may be used as a binder for pigments while also providing a hydrophobic functionality.

Hydrophilic pigments may be carried in a solvent which may include ketones such as acetone or methylethylketone; alkanols such as ethanol or ethylene glycol, ethers such as diethylether; esters such as ethylacetate, and acetonitrile, at the time of application. Solvents may be used to form a portion of the plasma polymerised coating on the article after exposure to plasma, or may be evaporated or substantially removed from the article before a plasma polymerised coating is applied to the article.

Hydrophobic performance, or superhydrophobic performance may be provided by the plasma polymerised coating alone, by the pigment alone, or by a combination of the two. Similarly, hydrophilic coatings may also be provided in a similar manner.

Soft hand feel may also be imparted with the use of at least one of pigments and/or a plasma polymerised coating. Soft handfeel is generally a metric for textiles or garments wherein the handfeel of the substrate or textile being treated generally does not change relative to the untreated substrate or textile handfeel, or softens the handfeel further. Softer handfeel may also relate to drapability of the substrate or textile. A primary advantage of using a plasma polymerisation to generate a plasma polymerised coating on a substrate may allow for a functionality to be imparted as well as providing for an improved handfeel. This may be particularly true with respect to plasma coatings which are applied with chemistry, monomer, or precursors being passed through a plasma region generated by a module 20 before being applied to a substrate.

Alternatively, thinner coatings may be applied by a mister, vaporiser or atomiser before being subjected to a plasma region to be polymerised. However, the difficulties of this application method may cause agglomeration or consolidation of the fluids applied which can cause uneven coatings to be provided under suboptimal conditions, or if the time between application and plasma treatment is too great.

Application of a plasma polymerised coating to the article is preferred to occur during a plasma exposure step, or allowing chemistry, monomer, or precursors to pass through a plasma region before application to the article. This is due to the fact that the thickness of the coating can be controlled more than with conventional coating application methods, such as dipping, knife coating, or spraying. Chemistry, monomer, or precursors entering into the plasma region, preferably in droplets, vapour or an aerosolised state may be readily fractionated and polymerised on the substrate to form a highly cross-linked structure which may then be deposited onto the article, wherein the coating or film can build or grow as desired. Development of a coating or film in this manner can reduce the overall consumption of material required to achieve a desired functional coating on an article 1.

A self-cleaning or anti-odour CuO, TiO₂, and/or AgNO₃ pigment may be applied to an article 1 in which ions from the copper or silver may diffuse to the surface of the plasma polymerised coating the pigments are embedded within and promote an adverse environment for bacteria, microorganisms, viruses or other biological matter. Alternatively, the self-cleaning coating may be the primary coating applied to an article 1 which provides a self-cleaning coating. When exposed to sunlight these coatings may react with water to generate hydroxyl radicals. These radicals may break down organic molecules and microbes adsorbed on the surface of the coating. Fluids, such as water, may be applied to the coating which can be absorbed and allows for dust, dirt, oil, and other contaminants on the surface to be removed, or substantially removed. Other self-cleaning coatings may also be applied, and may have different activation or cleaning reactions, however it will be understood that any self-cleaning coating may be applied by the system 10.

Self-cleaning coatings may have applications for garments, medical devices, commonly touched articles, vehicles, aeroplanes and public facilities. Multiple coatings may be applied, or reapplied, to an article 1 such that desired properties can remove dirt, stains, oils, or other predetermined contaminants.

Photocatalytic self-cleaning fabrics use a variety of semiconducting materials, including titanium dioxide (TiO₂), zinc oxide (ZnO), and silica (SiO₂), among others. There are three distinct crystalline forms of TiO₂: anatase, rutile, and brookite. TiO₂ may be used as a photocatalytic hydrophilic pigment which is predominantly composed of rutile and anatase phases.

Some pigments may also be applied to an article which may be beneficial for anti-friction coatings. Solid lubricants may be distributed to the article which may act as the anti-friction coating. Lubricant pigments may also have utility in relation to corrosion resistance for articles or may have utility in relation to flame retardancy. Anti-friction coatings form a slippery film, which covers all surface roughness and thus optimises metal-to-metal, metal-to-plastic or plastic-to-plastic friction even under extreme loads and working conditions. Some examples of anti-friction pigments which may be included within a coating may include a material selected from the following non-exhaustive list; molybdenum sulfide (MoS), molybdenum disulfide (MoS₂), PTFE, graphite, and special pigments. Further, pigments and coatings may be applied to improve the colourfastness of the article after treatment, or the handfeel of the article 1.

UV absorbing or photoprotective pigments may include Mycosporine-like amino acids (MAAs). MAAs may be used to block or absorb UV-A and UV-B and absorb UV rays within the range of 310 nm to 360 nm. Melanin pigment may also be used to protect against UV. In addition, carotenoids and photopigments may be used to act as photo-protective pigments, as they quench oxygen free-radicals. Carotenoids and photopigments may also be used to supplement photosynthetic pigments that absorb light energy in the blue region.

In another embodiment, the pigment used in the process to form a coating or film on an article may comprise a metal oxide, for example, at least one metal oxide from the following group; SiO₂, ZrO₂, TiO₂, Ta₂0₅, HfO₂, ThO₂, SnO₂, VO₂, In₂O3, CeO₂, CuO, CuS, FeCl₂, ZnO, Nb₂O₅, V₂O₅, Al₂O₃, Sc₂O₃, Ce₂O₃, NiO, MgO, Y₂O₃, WO₃, BaTiO₃, Fe₂O₃, Fe₃O₄, Sr₂O₃, TiO₃, Cr₂O₃, Mn₂O₃, Mn₃O₄, Cr₃O₄, MnO₂, RuO₂, or a combination of these oxides for example by doping the particles or by mixing the particles.

For coatings which are required to be biocompatible, the coating may be adapted to be used for invitro applications, and may optionally be a biopolymer as discussed herein. If this is desired, the monomer or precursor for the plasma may include at least one of the following materials; collagen, fibrin, fibrinogen, platelet-rich plasma, alginate, gelatin, albumin, and hyaluronic acid.

Other materials which may be injected or supplied to a plasma region may include terpene β-elemene. In addition, cyclic monomers may be used which are amenable to ring-opening polymerisation (ROP). These monomers may optionally also be suitable for ring-opening copolymerisation (ROCOP). Such suitable materials may include at least one or more materials from the following group: epoxides, cyclic trisiloxanes, cycloalkenes, lactones, lactides, cyclic carbonates, and amino acid N-carboxyanhydrides.

It will be appreciated that both anionic and cationic ring-opening polymerisation (AROP and CROP, respectively) may be achieved with the use of plasma polymerisation techniques. Furthermore, ring-opening metathesis polymerisation (ROMP) may also be possible with the use of plasma polymerisation techniques.

In yet a further embodiment, the system may be adapted to pre-treat or post treat an article. Pre-treatment or post-treatments may be any form of treatment the article may undergo to improve the interactions between at least one of the pigment and the plasma coating applied to the article 1. Any pre-treatment or post treatment may be provided outside of the system, but may be used to improve the plasma coating and pigment therein if desired. For example, a heat treatment process may be used to remove moisture from an article before treatment, or a heat treatment may assist with curing the plasma coating after processing. Other treatments may also be provided, such as a cleaning process, scouring process, ozone exposure, static cleaning, imparting a charge to the article, exposing the article to a predetermined radiation and/or light, or a plasma treatment. Any such treatment imparted to the article may improve the durability of the coating, the functional performance of the coating and/or the pigment within the coating, the hardness of the coating, the handfeel of the coating, the coating thickness, the colour of the coating or the underlying article, the appearance of the coating, and the lustre of the coating.

Single- and double-sided coatings may also be provided by the system. Single sided coatings, for example on a substrate article, may be applied from a series of treatment modules which are positioned to face a single side of the article. This may be exemplified in FIG. 1 wherein the treatments to the substrate article being treated are all facing a first side. A second side of the article may be treated during the same process if there are treatment modules positioned to face the second side of the substrate article. Alternatively, the first side treatment modules may be adapted to urge, force or propagate a coating from the first side of the article through to the second side of the article, thereby treating both the first and second sides of the article 1.

In yet a further embodiment, the system may pass the article through the system and treat a first side of the article, and be adapted to re-feed the article through the system with the modules facing the second side of the article during re-feeding. This may involve turning the article before re-feeding, or a repositioning of one or more modules within the system to allow for the treatment of the second side.

With the system 1 able to coat an article with multiple treatments, or single sided treatments, the article may have one or more different functionalities applied to it. For example, a substate with a hydrophobic treatment on a first side of a substrate may have a hydrophilic coating on the second side of the substrate. This may be of particular advantage if the substrate article is porous as the hydrophilic treatment may be used to wick and transfer moisture and the hydrophobic treatment may be used to transport and repel moisture in a desired manner. This may allow for a moisture wicking system which does not require the used of multiple membranes, adhesion process and complex structures to allow for a desired wicking effect. Other effects may also be anticipated whereby a first side of a substrate article may have a hydrophobic treatment applied thereto, and a hydrophilic treatment applied relatively on top of said hydrophobic treatment, and the second side of the substrate article may have a further hydrophobic and/or hydrophilic treatment applied thereto such that intermediate layers of the coatings applied thereto may be adapted for the transport of moisture.

Throughout this specification the term “treatment” may optionally be interchanged with the term “plasma polymerised coating”. Throughout this specification the term “pigment coating” may refer to a coating with a pigment which is formed with a plasma polymerised coating. Throughout this specification, the terms “precursor, chemistry or monomer” may be interchanged within specific embodiments such that the terms are non-limiting unless desired to exclude one or more types of monomer, chemistry, or precursor.

While specific examples of pigments have been discussed, the pigments for each application above mentioned may be suitable for one or more other functional applications and therefore any pigment mentioned herein may be used within any other embodiment disclosed herein as desired. Pigment sizes may optionally be in the nanoscale or microscale, and/or include a mixture of the two.

Although the invention has been described with reference to specific examples, it will be appreciated by those skilled in the art that the invention may be embodied in many other forms, in keeping with the broad principles and the spirit of the invention described herein.

The present invention and the described preferred embodiments specifically include at least one feature that is industrially applicable.

1. A system for coating an article, the system comprising;
a pigment applicator adapted to apply a pigment;
a plasma module adapted to generate a plasma region;
at least one of a chemistry and precursor supplied to the plasma generated such that the plasma region can at least in part polymerise the at least one of a chemistry and precursor to form a plasma polymerised coating; and
wherein the pigment is fixed to the article by the plasma polymerised coating.

2. The system as claimed in claim 1, further comprising a post-plasma treatment module adapted to treat the plasma polymerised coating.

3. The system as claimed in claim 1, wherein the pigment applicator is integral to the plasma module.

4. The system as claimed in claim 1, wherein the plasma module is contained within a chamber is locally purged to a purity of greater than 90% with a plasma gas.

5. The system as claimed in claim 4, wherein the entry to the chamber is fitted with a roller sealing the entry such that the plasma gas is generally retained within the chamber and ingress of external fluids is limited while also allowing the article to enter into the chamber.

6. The system as claimed in claim 1, wherein the pigment applied to the article is at least one of a; colourant, functional pigment, and a conductive pigment.

7. The system as claimed in claim 1, wherein the plasma module is adapted to supply the at least one of a chemistry and precursor to the plasma region such that the at least one of a chemistry and precursor forms a plasma polymerised molecule before being applied to the article to form a plasma polymerised coating.

8. An article with a plasma coating; the article comprising;
a surface on which pigment is deposited,
the pigment being bonded to the article by a plasma polymerised coating, and wherein the plasma polymerised coating was polymerised at a pressure of between 95 kPa to 105 kPa.

9. The article with a plasma coating as claimed in claim 8, wherein a further deposition of pigment is applied on the surface of the plasma polymerised coating.

10. The article with a plasma coating as claimed in claim 9, wherein the further deposition of pigment is fixed to the plasma polymerised coating by a further plasma polymerised coating.

11. The article as claimed in claim 8, wherein the pigment is provided to the article during a plasma polymerisation step, such that the pigment is bonded within the plasma polymerised coating at the time of application.

12. The article as claimed in claim 8, wherein the pigment is of a size which is relatively larger than the thickness of the coating.

13. The article as claimed in claim 8, wherein the pigment is a colourant which is a different colour than that of the article, such that the article is imparted generally with a shade or similar colour as that of the pigment colourant.

14. The article as claimed in claim 8, wherein the pigment is a functional pigment adapted to released ions and/or diffuse ions while bonded within the plasma polymerised coating.

15. The article as claimed in claim 8, wherein the plasma polymerised coating is finished by a post-plasma treatment step to cure or otherwise treat an exposed surface of the plasma polymerised coating.
